(19) United States
(12) Patent Application Publication
(10) Pub. No.: US 2022/0416508 A1
(43) Pub. Date: Dec. 29, 2022

(54) SEMICONDUCTOR LASER ELEMENT

(71) Applicant: Panasonic Holdings Corporation, Osaka (JP)

(72) Inventors: Hiroyuki HAGINO, Osaka (JP); Shinichiro NOZAKI, Osaka (JP)

(21) Appl. No.: 17/784,960

(22) PCT Filed: Nov. 10, 2020
(86) PCT No.: PCT/JP2020/041951

§ 371 Date: Jun. 13, 2022

(30) Foreign Application Priority Data
Dec. 17, 2019 (JP) 2019-227316

(51) Int. Cl. H01S 5/22; H01S 5/343; H01S 5/026

(52) U.S. Cl. CPC H01S 5/22; H01S 5/34333; H01S 5/026; H01S 5/34346

(57) ABSTRACT

The semiconductor laser element includes: a substrate; a first semiconductor layer disposed above a main surface of the substrate; an active layer that is disposed above the first semiconductor layer and generates light; and a second semiconductor layer) disposed above the active layer. In a top view of a front-side end portion of the semiconductor laser element from which the light is emitted, an end surface of the second semiconductor layer includes an inclined portion with respect to an end surface of the first semiconductor layer.

### CROSS-REFERENCE OF RELATED APPLICATIONS

This application is the U.S. National Phase under 35 U.S.C. § 371 of International Patent Application No. PCT/JP2020/041951, filed on Nov. 10, 2020, which in turn claims the benefit of Japanese Patent Application No. 2019-227316, filed on Dec. 17, 2019, the entire disclosures of which Applications are incorporated by reference herein.

### TECHNICAL FIELD

This disclosure relates to a semiconductor laser element.

### BACKGROUND ART

In recent years, semiconductor laser elements have attracted attention as light sources for various applications such as light sources for image display devices such as displays and projectors, light sources for in-vehicle head lamps, light sources for industrial lighting and consumer lighting, and light sources for industrial equipment such as laser welding devices, thin film annealing devices, and laser processing devices. In addition, a semiconductor laser element used as a light source for the above applications is desired to have an increased output of greatly exceeding 1 watt and a high beam quality.

To achieve high beam quality, it is desirable for the laser to oscillate in the basic transverse mode. In order to realize the basic transverse mode operation, there is a method of narrowing the width of the waveguide and operating it in a state where the higher-order transverse mode does not exist optically (cutoff state). However, in order to achieve an increased output, it is advantageous to have a wide waveguide (wide stripe), so the transverse mode of high-power laser beam such that the power of the output beam exceeds 1 watt is often a higher-order mode.

A conventional semiconductor laser element is disclosed in Patent Literature (PTL) 1. FIG. 14 is a schematic top view showing a configuration of conventional semiconductor laser device 914 disclosed in PTL 1.

Semiconductor laser device 914 described in PTL 1 is a semiconductor device in which a plurality of semiconductor laser elements are monolithically formed, characterized in that the respective light emitting directions at the time of being emitted from respective emitting surfaces 917 of the plurality of semiconductor laser elements are different. The portions of waveguide 911, waveguide 912, and waveguide 913 shown in FIG. 14 are light emitting portions corresponding to a single semiconductor laser element, respectively, and array-type semiconductor laser device 914 is formed by these waveguides. Reflective film 915 shown in FIG. 14 is a coating that increases the reflectance and protects end surface 916 of semiconductor laser device 914.

### CITATION LIST

### Patent Literature

[PTL 1] Japanese Unexamined Patent Application Publication No. S62-269385

### SUMMARY OF INVENTION

### Technical Problem

In this way, since the emission end of the waveguide is inclined, the reflectance of the higher-order transverse modes at the emission end is reduced relative to the reflectance of the basic transverse mode, and the higher-order transverse mode components can be suppressed to some extent. However, especially in a wide waveguide used for an increased output, the light confinement action in the lateral direction is weak. For that reason, a higher-order transverse mode component can be generated with a slight temperature change. Due to this higher-order transverse mode component, there is a problem that ripples occur in the output light distribution of the semiconductor laser.

An object of the present disclosure is to provide a semiconductor laser element capable of suppressing ripples in an output light distribution.

In order to achieve the above object, one aspect of the semiconductor laser element according to the present disclosure is a semiconductor laser element, including: a substrate; a first semiconductor layer disposed above a main surface of the substrate; an active layer that is disposed above the first semiconductor layer and generates light; and a second semiconductor layer disposed above the active layer. In a top view of a front-side end portion of this semiconductor laser element from which the light is emitted, an end surface of the second semiconductor layer includes an inclined portion with respect to an end surface of the first semiconductor layer.

Due to the inclination of the end surfaces of the second semiconductor layer, the reflectance of the laser beam resonating in the semiconductor laser element in the resonance direction decreases. Here, the decrease in reflectance is more remarkable in the higher-order transverse mode components than in the basic transverse mode component. In addition, since the inclinations of the first semiconductor layer and the second semiconductor layer are different, the reflectance for the higher-order transverse mode components in the resonance direction can be further reduced selectively. That is, the higher-order transverse mode components can be selectively reduced at the front-side end portion. Therefore, it is possible to suppress the ripples caused by the higher-order transverse mode components in the output light distribution.

In addition, in one aspect of the semiconductor laser element according to the present disclosure, in a top view of a rear-side end portion, which is an end portion opposite to the front-side end portion, an end surface of the second semiconductor layer may include an inclined portion with respect to an end surface of the first semiconductor layer.

This makes it possible to reduce the higher-order transverse mode components selectively at the rear-side end portion as well as at the front-side end portion. Therefore, the ripples caused by the higher-order transverse mode components in the output light distribution can be further suppressed.

In addition, in one aspect of the semiconductor laser element according to the present disclosure, the inclined portion of the front-side end portion and the inclined portion of the rear-side end portion that is opposite to the inclined portion of this front-side end portion may not be parallel in the top view.

This makes it possible to suppress the resonance of the higher-order transverse mode components between the front-side end portion and the rear-side end portion. Therefore, the ripples caused by the higher-order transverse mode components in the output light distribution can be further suppressed.

In addition, in one aspect of the semiconductor laser element according to the present disclosure, the inclined portion of the front-side end portion and the inclined portion of the rear-side end portion may be tilted in a same direction with respect to the end surface of the first semiconductor layer around an axis perpendicular to the main surface.

This makes it possible to suppress the resonance of the higher-order transverse mode components between the front-side end portion and the rear-side end portion. Therefore, the ripples caused by the higher-order transverse mode components in the output light distribution can be further suppressed.

In addition, one aspect of the semiconductor laser element according to the present disclosure includes a plurality of waveguide portions arranged in an array, and in the top view of the front-side end portion, inclination angles of the end surface of the second semiconductor layer with respect to the end surface of the first semiconductor layer may differ from each other at positions corresponding to at least two of the plurality of waveguide portions.

This makes it possible to make the generated higher-order transverse mode components different in at least two of the plurality of waveguide portions. Therefore, the ripples contained in the light distributions of at least two laser beams are different. For this reason, when a plurality of laser beams emitted from the respective waveguide portions are combined, it is possible to suppress the ripples contained in the light distributions of at least two laser beams from intensifying each other. That is, it is possible to suppress the ripples in a combined laser beam generated by combining a plurality of laser beams.

In addition, one aspect of the semiconductor laser element according to the present disclosure includes a plurality of waveguide portions arranged in an array, and in the top view of the front-side end portion, inclination directions of the end surface of the second semiconductor layer with respect to the end surface of the first semiconductor layer may be same at positions corresponding to at least two of the plurality of waveguide portions.

In addition, in one aspect of the semiconductor laser element according to the present disclosure, in the top view of the front-side end portion, the inclination directions of the end surface of the second semiconductor layer with respect to the end surface of the first semiconductor layer may be same at positions corresponding to all of the plurality of waveguide portions.

In addition, in one aspect of the semiconductor laser element according to the present disclosure, in the top view of the front-side end portion, an inclination angle of the end surface of the second semiconductor layer with respect to the end surface of the first semiconductor layer may be 0.1 degrees or more.

This makes it possible to selectively reduce the higher-order transverse mode components more reliably at the front-side end portion. Therefore, the ripples caused by the higher-order transverse mode components in the output light distribution can be suppressed more reliably.

According to the semiconductor laser according to the present disclosure, it is possible to suppress the higher-order transverse mode and suppress the ripple components.

### BRIEF DESCRIPTION OF DRAWINGS

FIG. 1A is a schematic top view showing a configuration of a semiconductor laser element according to a First Embodiment.

FIG. 1B is a schematic first cross-sectional view showing the configuration of a semiconductor laser element according to the First Embodiment.

FIG. 1C is a schematic second cross-sectional view showing the configuration of a semiconductor laser element according to the First Embodiment.

FIG. 1D is a schematic top view showing a part of a front-side end portion of a semiconductor laser element according to the First Embodiment in an enlarged manner.

FIG. 1E is a schematic cross-sectional view showing the part of the front-side end portion of a semiconductor laser element according to the First Embodiment in an enlarged manner.

FIG. 2A is a cross-sectional view showing a step of forming each layer of a first semiconductor layer, a light emitting layer, and a second semiconductor layer in a method for manufacturing a semiconductor laser element according to the First Embodiment.

FIG. 2B is a top view showing a step of forming each layer of the first semiconductor layer, the light emitting layer, and the second semiconductor layer in the method for manufacturing a semiconductor laser element according to the First Embodiment.

FIG. 2C is a cross-sectional view showing a step of forming a first protective film in the method for manufacturing a semiconductor laser element according to the First Embodiment.

FIG. 2D is a top view showing the step of forming the first protective film in the method for manufacturing a semiconductor laser element according to the First Embodiment.

FIG. 2E is a cross-sectional view showing a step of patterning the first protective film in the method for manufacturing a semiconductor laser element according to the First Embodiment.

FIG. 2F is a top view showing a step of patterning the first protective film in the method for manufacturing a semiconductor laser element according to the First Embodiment.

FIG. 2G is a cross-sectional view showing a step of etching end portions in a resonance direction of p-side contact layer 43 and p-side clad layer 42 in the method for manufacturing a semiconductor laser element according to the First Embodiment.

FIG. 2H is a top view showing a step of etching p-side contact layer 43 and p-side clad layer 42 in the method for manufacturing a semiconductor laser element according to the First Embodiment.

FIG. 2I is a cross-sectional view showing a step of patterning first protective film 95 in a band shape in the method for manufacturing a semiconductor laser element according to the First Embodiment.

FIG. 2J is a top view showing a step of patterning first protective film 95 in a band shape in the method for manufacturing a semiconductor laser element according to the First Embodiment.

FIG. 2K is a first cross-sectional view showing a step of forming waveguide portion 40a in the method for manufacturing a semiconductor laser element according to the First Embodiment.

FIG. 2L is a top view showing a step of forming waveguide portion 40a in the method for manufacturing a semiconductor laser element according to the First Embodiment.

FIG. 2M is a second cross-sectional view showing a step of forming waveguide portion 40a in the method for manufacturing a semiconductor laser element according to the First Embodiment.

FIG. 2N is a cross-sectional view showing a step of forming a dielectric layer in the method for manufacturing a semiconductor laser element according to the First Embodiment.

FIG. 2P is a top view showing a step of forming a dielectric layer in the method for manufacturing a semiconductor laser element according to the First Embodiment.

FIG. 2Q is a cross-sectional view showing a step of forming a p-side electrode in the method for manufacturing a semiconductor laser element according to the First Embodiment.

FIG. 2R is a top view showing a step of forming a p-side electrode in the method for manufacturing a semiconductor laser element according to the First Embodiment.

FIG. 2S is a cross-sectional view showing a step of forming a pad electrode in the method for manufacturing a semiconductor laser element according to the First Embodiment.

FIG. 2T is a top view showing a step of forming a pad electrode in the method for manufacturing a semiconductor laser element according to the First Embodiment.

FIG. 2U is a cross-sectional view showing a step of forming an n-side electrode in the method for manufacturing a semiconductor laser element according to the First Embodiment.

FIG. 3A is a schematic plan view showing a mounting form of the semiconductor laser element according to the First Embodiment.

FIG. 3B is a schematic cross-sectional view showing the mounting form of the semiconductor laser element according to the First Embodiment.

FIG. 4A is a schematic top view showing a part of a front-side end portion of the semiconductor laser element according to a First Variation of the First Embodiment in an enlarged manner.

FIG. 4B is a schematic top view showing a part of a front-side end portion of the semiconductor laser element according to a Second Variation of the First Embodiment in an enlarged manner.

FIG. 4C is a schematic top view showing a part of a front-side end portion of the semiconductor laser element according to a Third Variation of the First Embodiment in an enlarged manner.

FIG. 4D is a schematic top view showing a part of a front-side end portion of the semiconductor laser element according to a Fourth Variation of the First Embodiment in an enlarged manner.

FIG. 5A is a schematic cross-sectional view showing a part of a front-side end portion of a semiconductor laser element according to a Fifth Variation of the First Embodiment in an enlarged manner.

FIG. 5B is a schematic cross-sectional view showing a part of a front-side end portion of a semiconductor laser element according to a Sixth Variation of the First Embodiment in an enlarged manner.

FIG. 6A is a schematic top view showing a part of a front-side end portion of the semiconductor laser element according to a Second Embodiment in an enlarged manner.

FIG. 6B is a schematic cross-sectional view showing a part of a front-side end portion of the semiconductor laser element according to the Second Embodiment in an enlarged manner.

FIG. 7A is a schematic cross-sectional view showing a step of forming each layer of a first semiconductor layer, a light emitting layer, and a second semiconductor layer in a method for manufacturing a semiconductor laser element according to the Second Embodiment.

FIG. 7B is a schematic cross-sectional view showing a step of forming a first protective film in the method for manufacturing a semiconductor laser element according to the Second Embodiment.

FIG. 7C is a schematic cross-sectional view showing a step of patterning the first protective film in the method for manufacturing a semiconductor laser element according to the Second Embodiment.

FIG. 7D is a schematic cross-sectional view showing a step of forming a waveguide portion in the method for manufacturing a semiconductor laser element according to the Second Embodiment.

FIG. 7E is a schematic cross-sectional view showing a step of forming a dielectric layer in the method for manufacturing a semiconductor laser element according to the Second Embodiment.

FIG. 7F is a schematic cross-sectional view showing a step of forming a p-side electrode in the method for manufacturing a semiconductor laser element according to the Second Embodiment.

FIG. 7G is a schematic cross-sectional view showing a step of forming a pad electrode in the method for manufacturing a semiconductor laser element according to the Second Embodiment.

FIG. 7H is a schematic cross-sectional view showing a step of forming an n-side electrode in the method for manufacturing a semiconductor laser element according to the Second Embodiment.

FIG. 7I is a schematic top view showing a step before forming grooves in the method for manufacturing a semiconductor laser element according to the Second Embodiment.

FIG. 7J is a schematic top view showing a step of forming grooves extending in the resonance direction in the method for manufacturing a semiconductor laser element according to the Second Embodiment.

FIG. 7K is a schematic top view showing a step of forming a groove between adjacent pad electrodes in the resonance direction in the method for manufacturing a semiconductor laser element according to the Second Embodiment.

FIG. 7L is a schematic top view showing a step of forming bar-shaped members in the method for manufacturing a semiconductor laser element according to the Second Embodiment.

FIG. 7M is a schematic top view showing a step of forming grooves for singulation in the method for manufacturing a semiconductor laser element according to the Second Embodiment.

FIG. 7N is a schematic top view showing a singulation step in the method for manufacturing a semiconductor laser element according to the Second Embodiment.

FIG. 8A is a schematic top view showing a part of a front-side end portion of a semiconductor laser element according to a variation of the Second Embodiment in an enlarged manner.

FIG. 8B is a schematic cross-sectional view showing a part of the front-side end portion of a semiconductor laser element according to the Variation of the Second Embodiment in an enlarged manner.

FIG. 9 is a schematic top view showing a part of a front-side end portion of a semiconductor laser element according to a Third Embodiment in an enlarged manner.

FIG. 10A is a schematic top view showing a configuration of a semiconductor laser element according to a Fourth Embodiment.

FIG. 10B is a schematic cross-sectional view showing the configuration of a semiconductor laser element according to the Fourth Embodiment.

FIG. 11 shows graphs showing an example of the light density distributions of laser beams emitted from the respective waveguide portions according to the Fourth Embodiment.

FIG. 12 is a schematic diagram showing an optical system that condenses five laser beams emitted from semiconductor laser elements according to the Fourth Embodiment to one point.

FIG. 13 is a graph showing the light density distribution of a combined light beam in which five laser beams emitted from the semiconductor laser elements according to the Fourth Embodiment are focused by the optical system shown in FIG. 12.

FIG. 14 is a schematic top view showing a configuration of a conventional semiconductor laser device disclosed in PTL 1.

### DESCRIPTION OF EMBODIMENTS

Hereinafter, embodiments of the present disclosure will be described with reference to the drawings. It should be noted that each of the embodiments described below show a specific example of the present disclosure. Therefore, the numerical values, shapes, materials, components, arrangement positions and connection forms of the components, steps and the order of the steps, and the like shown in the following embodiments are examples and are not intended to limit the present disclosure.

In addition, each figure is a schematic view and is not necessarily exactly illustrated. Therefore, the scales and the like do not always match in each figure. In each figure, substantially the same configuration is designated by the same reference numeral, and duplicate description will be omitted or simplified.

In addition, in the present specification, the terms “above” or “upper” and “below” or “lower” do not refer to the upward direction (vertically upward) and the downward direction (vertically downward) in absolute spatial recognition, but are used as terms defined by the relative positional relationship based on the stacking order in the stacked configuration. In addition, the terms “above” and “below” are applied to not only when the two components are spaced apart from each other and another component exists between the two components, but also when the two components are disposed in contact with each other.

In addition, in the present specification and the drawings, the X-axis, the Y-axis, and the Z-axis represent the three axes of the three-dimensional Cartesian coordinate system. The X-axis and the Y-axis are axes which are orthogonal to each other and both of which are orthogonal to the Z-axis.

### First Embodiment

The semiconductor laser element according to the First Embodiment will be described.

### [1-1. Configuration of Semiconductor Laser Element]

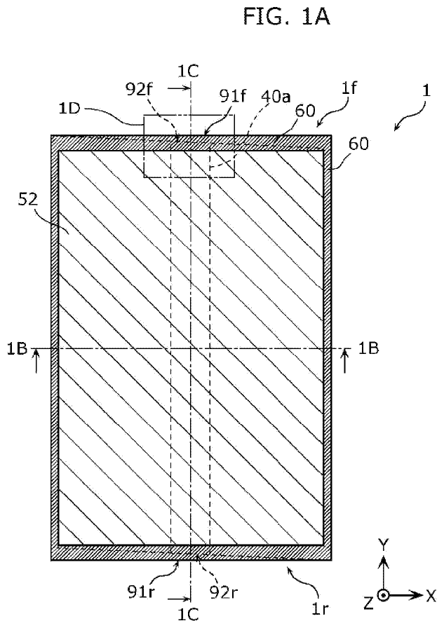

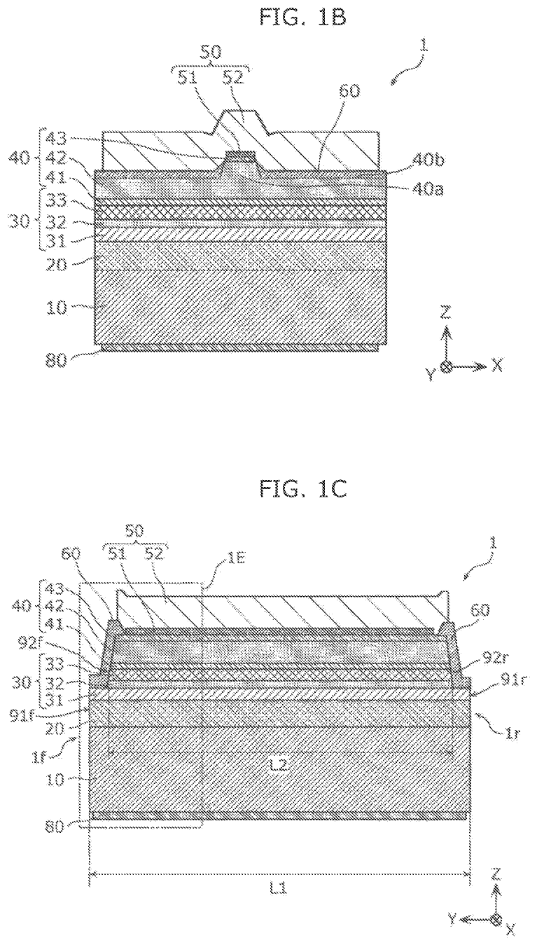

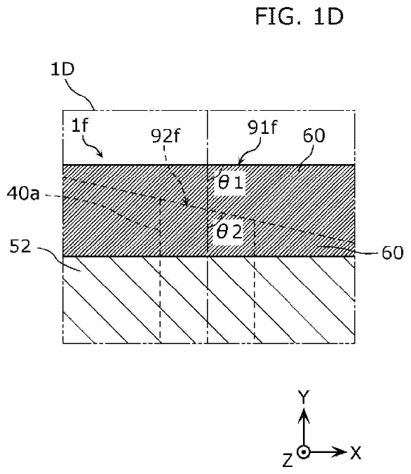

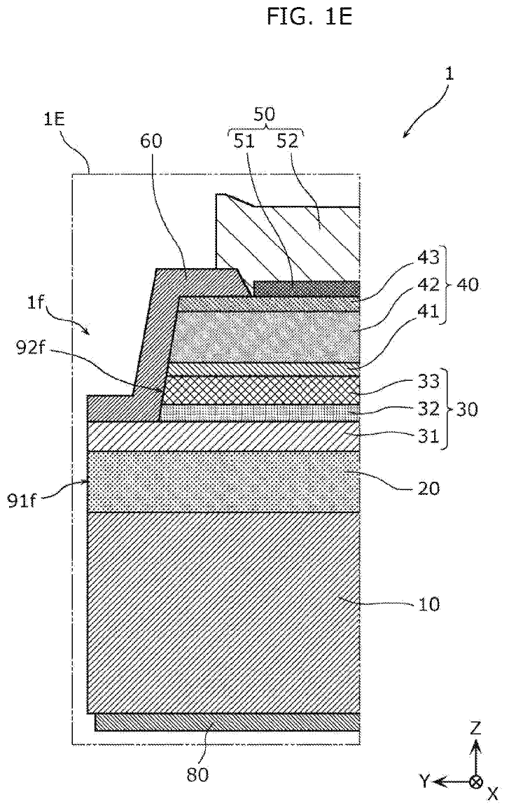

First, the configuration of the semiconductor laser element according to the present embodiment will be described with reference to FIG. 1A to FIG. 1E. FIG. 1A is a schematic top view showing the configuration of semiconductor laser element 1 according to the present embodiment. FIG. 1A is a plan view that is viewed from the top of the main surface of substrate 10 of semiconductor laser element 1 on which each semiconductor layer is stacked. FIG. 1B and FIG. 1C are schematic cross-sectional views showing the configuration of semiconductor laser element 1 according to the present embodiment. In FIG. 1B, a cross section of semiconductor laser element 1 taken along 1B-1B shown in FIG. 1A is illustrated. In FIG. 1C, a cross section of semiconductor laser element 1 taken along 1C-1C shown in FIG. 1A is illustrated. FIG. 1D is a schematic top view showing a part of front-side end portion 1f of semiconductor laser element 1 according to the present embodiment in an enlarged manner. In FIG. 1D, the inside of alternate long and two short dashes line frame 1D shown in FIG. 1A is illustrated. FIG. 1E is a schematic cross-sectional view showing a part of front-side end portion 1f of semiconductor laser element 1 according to the present embodiment in an enlarged manner. In FIG. 1E, the inside of alternate long and two short dashes line frame 1E shown in FIG. 1C is illustrated.

Semiconductor laser element 1 is an element that emits a laser beam that resonates between front-side end portion 1f and rear-side end portion 1r from front-side end portion 1f. In the present embodiment, semiconductor laser element 1 is a semiconductor laser element including a nitride-based semiconductor material. As shown in FIG. 1B, semiconductor laser element 1 includes substrate 10, first semiconductor layer 20, light emitting layer 30, second semiconductor layer 40, electrode member 50, dielectric layer 60, and n-side electrode 80. It should be noted that the resonance direction of the laser beam in semiconductor laser element 1 is defined as the Y axis, the direction perpendicular to the main surface of substrate 10 is defined as the Z axis, and the direction perpendicular to both the Y axis and the Z axis is defined as the X axis. The direction from rear-side end portion 1r toward front-side end portion 1f is defined as the positive direction of the Y axis. In addition, the direction from the main surface of substrate 10 toward first semiconductor layer 20 is defined as the positive direction of the Z axis.

Substrate 10 is, for example, a GaN substrate. In the present embodiment, an n-type hexagonal GaN substrate having a main surface of the (0001) plane is used as substrate 10. The thickness of substrate 10 may be any thickness as long as it can be cleaved when semiconductor laser element 1 is singulated, and is, for example, 50 μm or more and 130 μm or less. In the present embodiment, the thickness of substrate 10 is 90 μm.

First semiconductor layer 20 is a semiconductor layer disposed above the main surface of substrate 10. In the present embodiment, first semiconductor layer 20 comprises a nitride-based semiconductor material. First semiconductor layer 20 is, for example, an n-side clad layer comprising n-type Al_{0.03}Ga_{0.97}N and having a thickness of 3 μm.

Light emitting layer 30 is a semiconductor layer disposed above first semiconductor layer 20. In the present embodiment, light emitting layer 30 comprises a nitride semiconductor material. For example, light emitting layer 30 has a stacked structure in which n-side light guide layer 31, active layer 32, and p-side light guide layer 33 are stacked in order from the first semiconductor layer 20 side, as shown in FIG. 1B.

N-side light guide layer 31 is a layer that guides light to the vicinity of active layer 32, and has a higher refractive index than first semiconductor layer 20. In the present embodiment, n-side light guide layer 31 is an n-type GaN layer having a film thickness of 0.2 μm.

Active layer 32 is a layer that is disposed above first semiconductor layer 20 and generates light. In the present embodiment, active layer 32 has two In_{0.06}Ga_{0.94}N quantum well layers each having a film thickness of 5 nm and three In_{0.02}Ga_{0.98}N barrier layers each having a film thickness of 10 nm disposed alternately with the quantum well layer. That is, each quantum well layer is sandwiched between two barrier layers. It should be noted that the number of quantum well layers is not limited to two, and may be one or three or more.

P-side light guide layer 33 is a layer that guides light to the vicinity of active layer 32, and has a higher refractive index than second semiconductor layer 40. In the present embodiment, p-side light guide layer 33 is a p-type GaN layer having a film thickness of 0.1 μm.

Second semiconductor layer 40 is a semiconductor layer disposed above light emitting layer 30. In the present embodiment, second semiconductor layer 40 comprises a nitride-based semiconductor material. Second semiconductor layer 40 includes waveguide portion 40a that is a striped (in other words, ridge-shaped) convex portion extending in the resonance direction of the laser beam (that is, the Y-axis direction in each figure), and flat portion 40b extending laterally (that is, in the X-axis direction of each figure) from the base of waveguide portion 40a.

The width of waveguide portion 40a (that is, the dimension in the X-axis direction of each figure) is not particularly limited, but as an example, it is 1 μm or more and 100 μm or less. In order to operate semiconductor laser element 1 with a high light output (for example, watt class), the width of waveguide portion 40a may be 10 μm or more and 50 μm or less. In the present embodiment, the width of waveguide portion 40a is 30 μm.

The height of waveguide portion 40a (that is, the dimension in the Z-axis direction of each figure) is not particularly limited, but as an example, it is 100 nm or more and 1 μm or less. In order to operate semiconductor laser element 1 with a high light output (for example, watt class), the height of waveguide portion 40a may be set to 300 nm or more and 800 nm or less. In the present embodiment, the height of waveguide portion 40a is 600 nm.

As shown in FIG. 1B, second semiconductor layer 40 includes a stacked structure stacked by electron barrier layer 41 comprising AlGaN, p-side clad layer 42 comprising a p-type AlGaN layer, and A-side contact layer 43 comprising p-type GaN in order from the light emitting layer 30 side. P-side contact layer 43 is formed as the uppermost layer of waveguide portion 40a.

Electrode member 50 is disposed above second semiconductor layer 40. Electrode member 50 is wider than waveguide portion 40a. That is, the width of electrode member 50 (that is, the width in the X-axis direction) is larger than the width of waveguide portion 40a (width in the X-axis direction). Electrode member 50 is in contact with the upper surfaces of dielectric layer 60 and waveguide portion 40a.

In the present embodiment, electrode member 50 includes A-side electrode 51 for supplying a current to waveguide portion 40a, and pad electrode 52 disposed above p-side electrode 51.

P-side electrode 51 is in contact with the upper surface of waveguide portion 40a. P-side electrode 51 is an ohmic electrode that makes ohmic contact with p-side contact layer 43 above waveguide portion 40a, and is in contact with the upper surface of A-side contact layer 43 that is the upper surface of waveguide portion 40a. P-side electrode 51 is formed by using a metal material such as Pd, Pt, Ni, or the like. In the present embodiment, p-side electrode 51 has a two-layer structure in which a Pd layer and a Pt layer are stacked in order from the p-side contact layer 43 side.

As shown in FIG. 1C, p-side electrode 51 is not formed on the peripheral edge of the end portion of semiconductor laser element 1. That is, semiconductor laser element 1 includes a current non-injection region to which no current is supplied at the end portion.

Dielectric layer 60 is formed on p-side contact layer 43 in a portion (current non-injection region) where p-side electrode 51 is not formed. In addition, the cross-sectional shape of the region where p-side electrode 51 is formed has the structure shown in FIG. 1B at any portion.

Pad electrode 52 is wider than waveguide portion 40a and is in contact with dielectric layer 60. That is, pad electrode 52 is formed so as to cover p-side electrode 51 and dielectric layer 60. Pad electrode 52 is formed by using a metal material such as Ti, Ni, Pt, Au, or the like. In the present embodiment, pad electrode 52 has a three-layer structure in which a Ti layer, a Pt layer, and an Au layer are stacked in order from the p-side electrode 51 side.

It should be noted that as shown in FIG. 1A, pad electrode 52 is formed inside second semiconductor layer 40 in order to improve the yield when semiconductor laser element 1 is singulated. That is, when semiconductor laser element 1 is viewed from the top, pad electrode 52 is not formed on the peripheral edge of the end portion of semiconductor laser element 1.

As shown in FIG. 1C, pad electrode 52 is also formed on dielectric layer 60 formed on the side of the end portion relative to A-side electrode 51. When the film thickness of dielectric layer 60 is thicker than that of p-side electrode 51, the shape of pad electrode 52 becomes a raised shape at the end portion.

Dielectric layer 60 is an insulating film formed on the side surface of waveguide portion 40a in order to confine light. Specifically, dielectric layer 60 is continuously formed from the side surface of waveguide portion 40a (that is, the surface intersecting the X-axis direction in FIG. 1B) to flat portion 40b. In the present embodiment, dielectric layer 60 is continuously formed around waveguide portion 40a over the side surface of p-side contact layer 43, the side surface of the convex portion of p-side clad layer 42, and the upper surface of p-side clad layer 42. In the present embodiment, dielectric layer 60 is formed of a silicon oxide film (SiO₂).

The shape of dielectric layer 60 is not particularly limited, but dielectric layer 60 may be in contact with the side surface of waveguide portion 40a and flat portion 40b. Accordingly, the light generated directly under waveguide portion 40a can be stably confined.

In addition, in a semiconductor laser element for the purpose of operating with high light output (that is, high output operation), an end surface coating film such as a dielectric multilayer film is formed on the light emitting end surface. It is difficult to form this end surface coating film only on the end surface, and it also wraps around the upper surface of semiconductor laser element 1. In this case, since pad electrode 52 is not formed at the end portion of semiconductor laser element 1 in the resonance direction (that is, the Y-axis direction in each figure), if the end surface coating film wraps around to the upper surface, dielectric layer 60 and the end surface coating film may come into contact with each other at the end portion of semiconductor laser element 1 in the resonance direction. At this time, if dielectric layer 60 is not formed, or if the film thickness of dielectric layer 60 is thin for the light confinement, light is affected by the end surface coating film, which causes light loss. Therefore, the film thickness of dielectric layer 60 may be 100 nm or more in order to sufficiently confine the light generated in light emitting layer 30. On the other hand, if the film thickness of dielectric layer 60 is too thick, it becomes difficult to form pad electrode 52, so that the film thickness of dielectric layer 60 may be smaller than or equal to the height of waveguide portion 40a.

In addition, on the side surface of waveguide portion 40a and flat portion 40b, etching damage may remain in the etching step when forming waveguide portion 40a and a leakage current may be generated, but it is possible to reduce the generation of unnecessary leakage current by covering waveguide portion 40a and flat portion 40b with dielectric layer 60.

N-side electrode 80 is an electrode disposed below substrate 10 and is an ohmic electrode that makes ohmic contact with substrate 10. N-side electrode 80 has, for example, a stacked structure in which a Ti layer, a Pt layer, and an Au layer are stacked in order from the substrate 10 side. The configuration of n-side electrode 80 is not limited thereto. N-side electrode 80 may have a stacked structure in which a Ti layer and an Au layer are stacked.

Each layer described above can be formed with an almost uniform film thickness by adjusting the growth conditions.

### [1-2. Structure of End Portion]

Next, the structure of the end portion of semiconductor laser element 1 according to the present embodiment will be described with reference to FIG. 1A to FIG. 1E.

As shown in FIG. 1A and FIG. 1C to FIG. 1E, a flat surface portion (end surface) formed by the end surfaces of substrate 10, first semiconductor layer 20 and n-side light guide layer 31 at front-side end portion 1f of semiconductor laser element 1 is defined as first end surface 91f. In other words, the end surface of the semiconductor layer and substrate 10 below active layer 32 of front-side end portion 1f is defined as first end surface 91f. In addition, a flat surface portion (end surface) formed by the end surfaces of p-side light guide layer 33 and second semiconductor layer 40 at front-side end portion 1f of semiconductor laser element 1 is defined as second end surface 92f. In other words, the end surface of the semiconductor layer above active layer 32 of front-side end portion 1f is defined as second end surface 92f.

Similarly, as shown in FIG. 1A, a flat surface portion (end surface) formed by the end surfaces of substrate 10, first semiconductor layer 20 and n-side light guide layer 31 at rear-side end portion 1r of semiconductor laser element 1 is defined as first end surface 91r. In other words, the end surfaces of the semiconductor layer and substrate 10 below active layer 32 at rear-side end portion 1r is defined as first end surface 91r. In addition, a flat surface portion (end surface) formed by the end surfaces of A-side light guide layer 33 and second semiconductor layer 40 at rear-side end portion 1r of semiconductor laser element 1 is defined as second end surface 92r. In other words, the end surface of the semiconductor layer above active layer 32 at rear-side end portion 1r is defined as second end surface 92r.

As shown in FIG. 1C and FIG. 1E, active layer 32 and the layer above it are disposed inside n-side light guide layer 31. In other words, the end surface of active layer 32 and second end surface 92f are disposed inside first end surface 91f. Therefore, as shown in FIG. 1C, if the length of n-side light guide layer 31 in the Y-axis direction is defined as L1 and the length of p-side light guide layer 33 in the Y-axis direction is defined as L2, the relationship of L1>L2 is satisfied.

As shown in FIG. 1A and FIG. 1D, in the top view of front-side end portion 1f from which the light from active layer 32 of semiconductor laser element 1 is emitted, second end surface 92f includes a portion inclined with respect to first end surface 91f. In the present embodiment, almost the entire surface of second end surface 92f is inclined with respect to first end surface 91f. Here, the top view of front-side end portion 1f means that end portion 1f is viewed from above end portion 1f and from the positive direction of the Z axis. More specifically, in the top view of front-side end surface 1f, the end surface of second semiconductor layer 40, which is a part of second end surface 92f, includes a portion inclined with respect to the end surface of first semiconductor layer 20 which is a part of first end surface 91f. As shown in FIG. 1D, in the top view of front-side end portion 1f, with respect to respective angles θ1 and θ2 formed by (i) the resonance direction (that is, the Y-axis direction) and (ii) first end surface 91f and second end surface 92f, θ1≠θ2 holds.

Due to such inclination of the end surface of second semiconductor layer 40, the reflectance of the laser beam resonating in semiconductor laser element 1 in the resonance direction is decreased. Here, the decrease in reflectance is more remarkable in the higher-order transverse mode components than in the basic transverse mode component. In addition, since the tilts of first semiconductor layer 20 and second semiconductor layer 40 are different, the reflectance of the higher-order transverse mode components in the resonance direction can be selectively reduced. That is, the higher-order transverse mode components can be selectively reduced at front-side end portion 1f. Therefore, it is possible to suppress the ripples caused by the higher-order transverse mode components in the output light distribution.

In the present embodiment, the inclination angle of the end surface of second semiconductor layer 40 with respect to the end surface of first semiconductor layer 20 is 0.1 degrees or more in the top view of front-side end portion 1f. That is, θ1−θ2≥0.1° or θ1−θ2≤0.1° holds.

Accordingly, the higher-order transverse mode components can be selectively reduced more reliably at front-side end portion 1f.

In FIG. 1C to FIG. 1E, front-side end portion 1f of semiconductor laser element 1 is shown, but even in the top view of rear-side end portion 1r (the top view of rear-side end portion 1r means that end portion 1r is viewed from above end portion 1r and from the positive direction of the Z axis), the end surface of second semiconductor layer 40 which is a part of second end surface 92r includes a portion inclined with respect to the end surface of first semiconductor layer 20 which is a part of first end surface 91r. Accordingly, the higher-order transverse mode components can be selectively reduced at front-side end portion 1f.

In the present embodiment, first end surface 91r and first end surface 91f shown in FIG. 1A are parallel to each other, and second end surface 92r and second end surface 92f are not parallel to each other. That is, an inclined portion of the end surface of second semiconductor layer 40 at front-side end portion 1f and an inclined portion of the end surface of second semiconductor layer 40 at the rear-side end portion that is opposite to the inclined portion on the front side are not parallel in the top view.

Accordingly, the resonance of the higher-order transverse mode components between front-side end portion 1f and rear-side end portion 1r can be suppressed.

In addition, in the present embodiment, the inclined portion of second semiconductor layer 40 at front-side end portion 1f and the inclined portion of second semiconductor layer 40 at rear-side end portion 1r are tilted in the same direction around an axis perpendicular to the main surface of substrate 10 with respect to the end surface of first semiconductor layer 20. In other words, in the top view of the main surface of substrate 10, both of the end surface at front-side end portion 1f of second semiconductor layer 40 and the end surface at rear-side end portion 1r are inclined in the clockwise direction from the end surface of first semiconductor layer 20 around an axis perpendicular to the main surface of substrate 10.

Accordingly, the resonance of the higher-order transverse mode components between front-side end portion 1f and rear-side end portion 1r can be suppressed.

In addition, in a semiconductor laser element for the purpose of operating with high light output (that is, high output operation), an end surface coating film such as a dielectric multilayer film is formed on the light emitting end surface (not shown). This end surface coating film is formed on each of front-side end portion 1f and rear-side end portion 1r. On front-side first end surface 91f, the end surface coating film is formed in contact with n-side light guide layer 31, first semiconductor layer 20, and substrate 10. On the other hand, on front-side second end surface 92f, the end surface coating film is formed in a state of being in contact with dielectric layer 60. Then, the reflectance differs between first end surface 91f and second end surface 92f due to the influence of the presence or absence of dielectric layer 60. Accordingly, the higher-order mode can be further reduced selectively. Similarly, with respect to rear-side end portion 1r, the reflectance differs between first end surface 91r and second end surface 92r, and thereby the higher-order mode can be further reduced selectively.

Regarding semiconductor laser element 1 according to the present embodiment, the wavelength of the laser beam was 405 nm and the light output was 3 W.

### [1-3. Method for Manufacturing Semiconductor Laser Element]

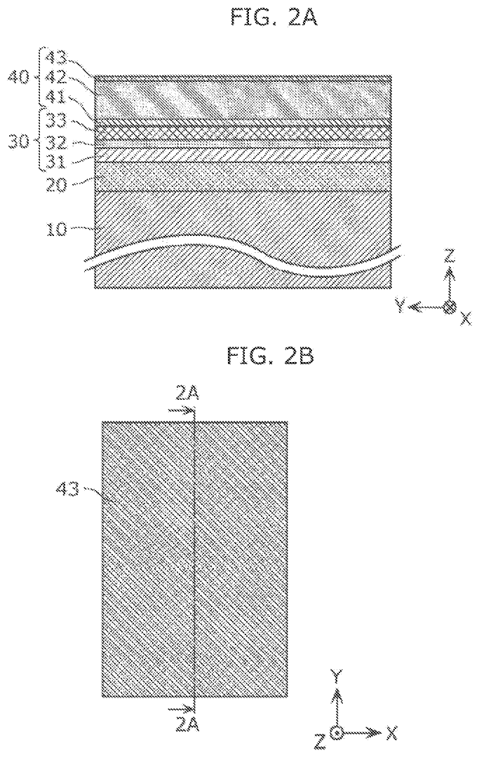

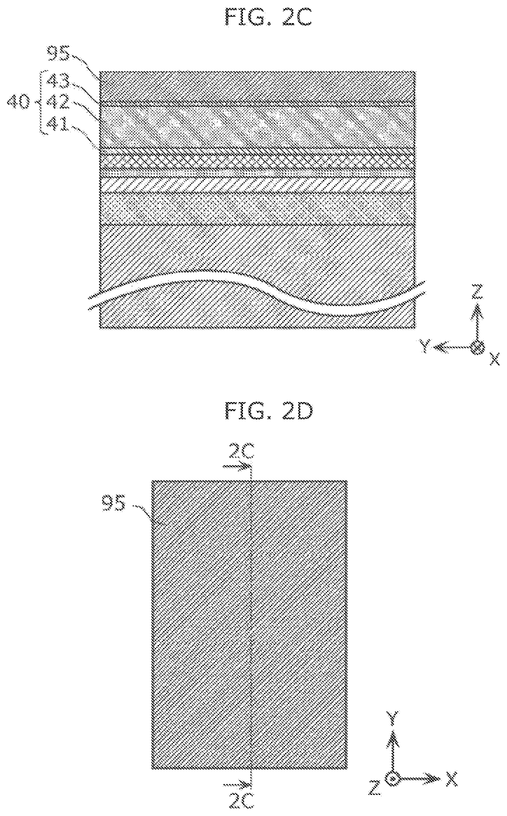

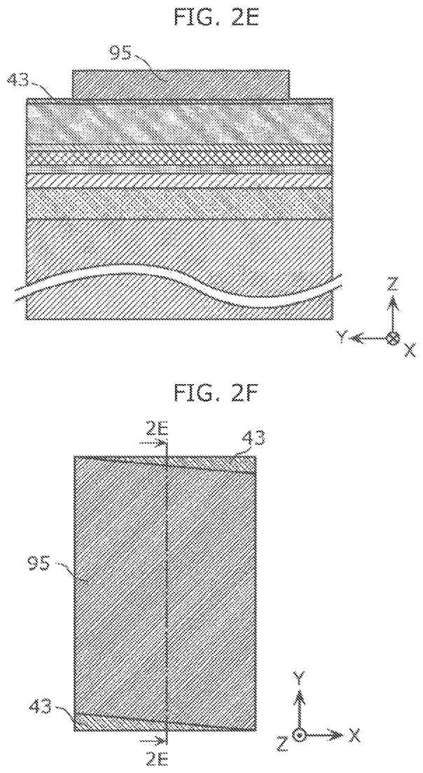

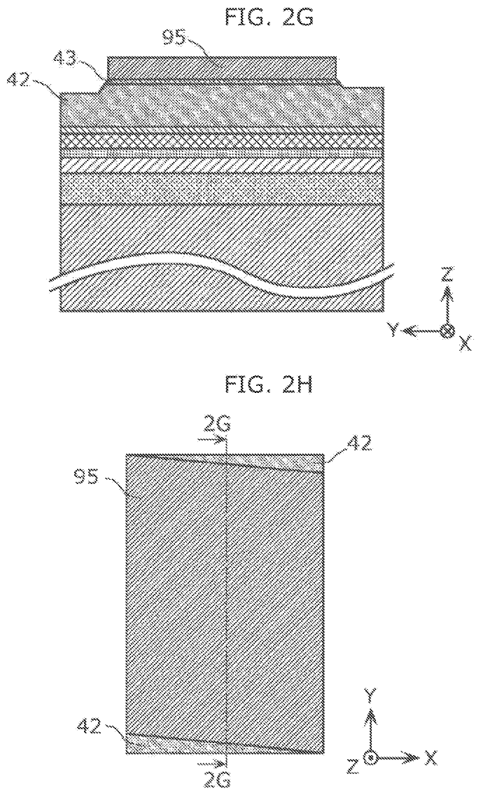

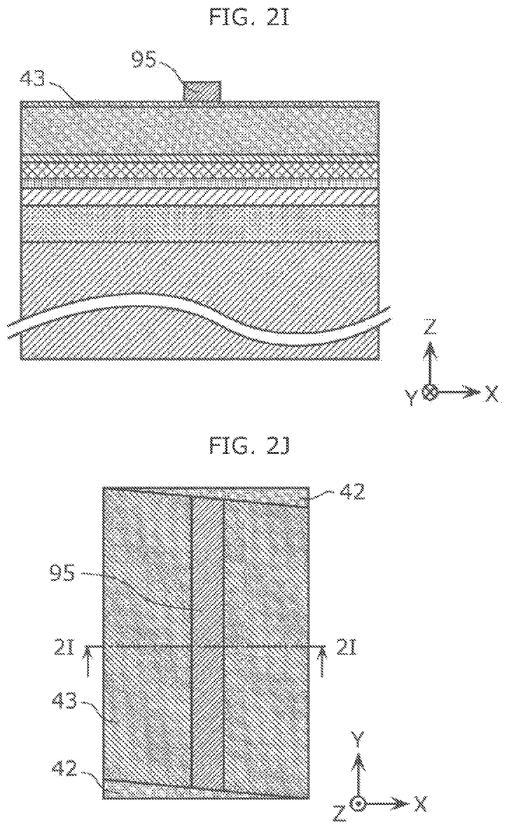

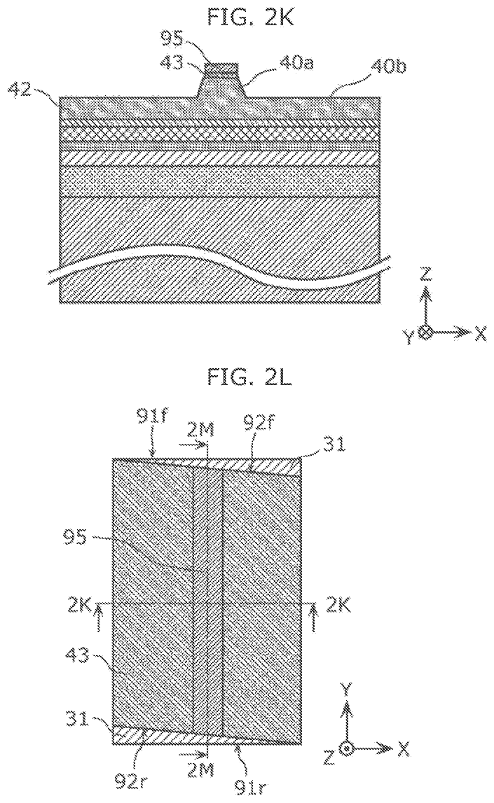

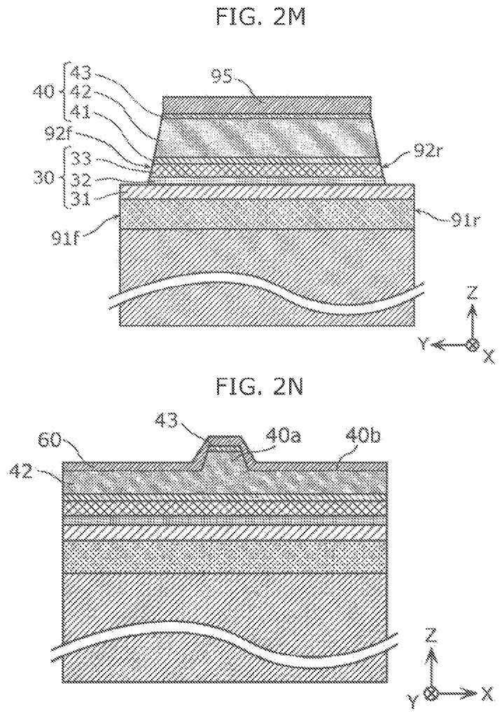

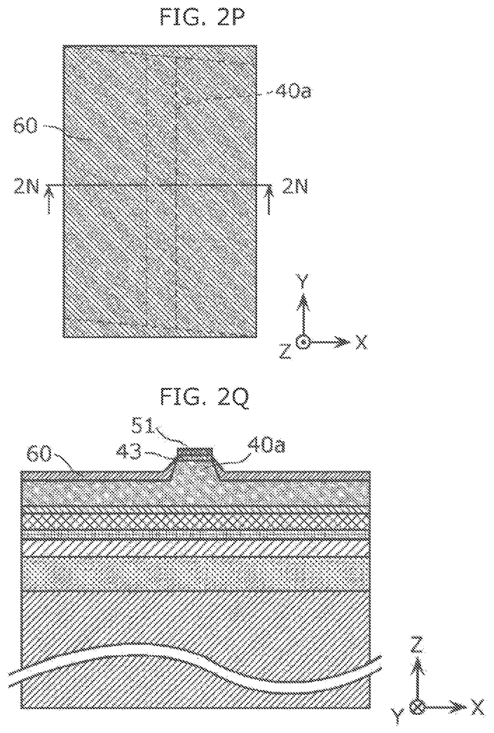

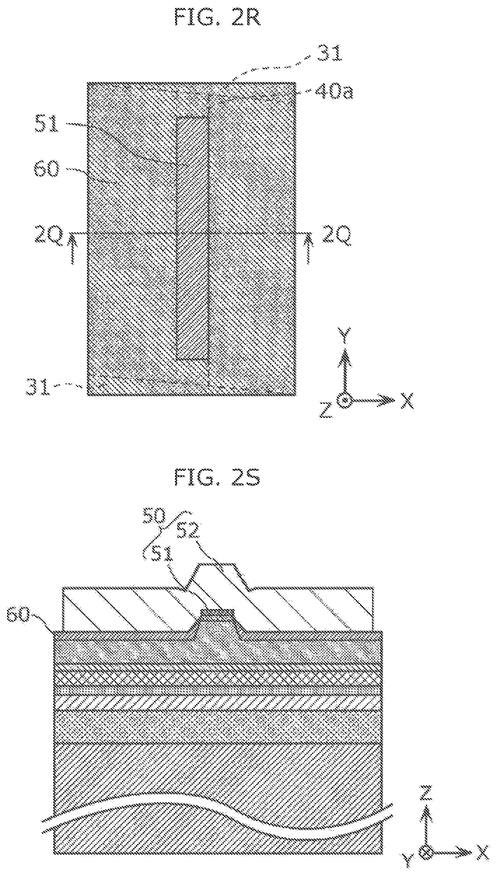

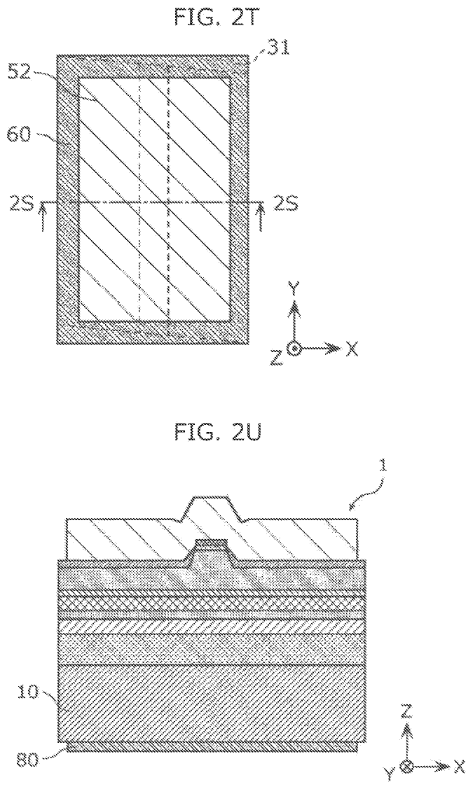

Next, the method for manufacturing semiconductor laser element 1 according to the present embodiment will be described with reference to FIG. 2A to FIG. 2U. FIG. 2A, FIG. 2C, FIG. 2E, FIG. 2G, FIG. 2I, FIG. 2K, FIG. 2M, FIG. 2N, FIG. 2Q, FIG. 2S, and FIG. 2U are schematic cross-sectional views which show steps in the method for manufacturing semiconductor laser element 1 according to the present embodiment. FIG. 2B, FIG. 2D, FIG. 2F, FIG. 2H, FIG. 2J, FIG. 2L, FIG. 2P, FIG. 2R, and FIG. 2T are schematic top views which show steps in the method for manufacturing semiconductor laser element 1 according to the present embodiment. FIG. 2A, FIG. 2C, FIG. 2E, FIG. 2G, FIG. 2I, FIG. 2K, FIG. 2M, FIG. 2N, FIG. 2Q, and FIG. 2S show the cross section taken along 2A-2A in FIG. 2B, the cross section taken along 2C-2C of FIG. 2D, the cross section taken along 2E-2E in FIG. 2F, the cross section taken along 2G-2G in FIG. 2H, the cross section taken along 2I-2I in FIG. 2J, the cross section taken along 2K-2K in FIG. 2L, the cross section taken along 2M-2M in FIG. 2L, the cross section taken along 2N-2N in FIG. 2P, the cross section taken along 2Q-2Q in FIG. 2R, and the cross section taken along 2S-2S in FIG. 2T, respectively.

First, as shown in FIG. 2A, first semiconductor layer 20, light emitting layer 30, and second semiconductor layer 40 are sequentially deposited on substrate 10 which is an n-type hexagonal GaN substrate having a main surface of the (0001) plane by using metalorganic chemical vapor deposition (MOCVD) method.

Specifically, an n-side clad layer comprising n-type Al_{0.03}Ga_{0.97}N is grown by 3 μm as first semiconductor layer 20 on substrate 10 having a thickness of 400 μm. Subsequently, n-side light guide layer 31 comprising n-type GaN is grown by 0.1 μm. Subsequently, active layer 32 including a barrier layer comprising In_{0.02}Ga_{0.98}N and a quantum well layer comprising In_{0.06}Ga_{0.94}N is grown. Subsequently, p-side light guide layer 33 comprising p-type GaN is grown by 0.1 μm. Subsequently, electron barrier layer 41 comprising AlGaN is grown by 10 nm. Subsequently, p-side clad layer 42 including a strained superlattice having a thickness of 0.48 μm formed by repeating a p-type AlGaN layer having a film thickness of 1.5 nm and a GaN layer having a film thickness of 1.5 nm for 160 cycles is grown. Subsequently, as shown in FIG. 2A and FIG. 2B, p-side contact layer 43 comprising p-type GaN is grown by 0.05 μm. Here, for example, trimethylgallium (TMG), trimethylammonium (TMA) and trimethylindium (TMI) are used as the organometallic raw materials containing Ga, Al, and In in each layer. In addition, ammonia (NH₃) is used as the nitrogen raw material.

Next, as shown in FIG. 2C and FIG. 2D, first protective film 95 is deposited on second semiconductor layer 40. Specifically, SiO₂ of 300 nm is deposited on p-side contact layer 43 as first protective film 95 by a plasma chemical vapor deposition (CVD) method using silane (SiH₄).

It should be noted that the deposition method of first protective film 95 is not limited to the plasma CVD method, and a known deposition method such as a thermal CVD method, a sputtering method, a vacuum vapor deposition method, or a pulse laser deposition method can be used. In addition, the depositing material of first protective film 95 is not limited to the above, and any material may be used as long as it has selectivity for etching of second semiconductor layer 40 (p-side clad layer 42, p-side contact layer 43) described later, such as a dielectric, a metal, or the like.

Next, as shown in FIG. 2E and FIG. 2F, only the end portion in the resonance direction of first protective film 95 is selectively removed so that any portion other than the end portion in the resonance direction of first protective film 95 remains by using the photolithography method and the etching method. In the present embodiment, the end portion of first protective film 95 is removed so that the end surface in the resonance direction of first protective film 95 is inclined with respect to the end surface in the resonance direction of p-side contact layer 43 in the top view. As the etching method, for example, dry etching such as reactive ion etching (RIE) using a fluorine-based gas such as CF₄, or wet etching such as hydrofluoric acid (HF) diluted to about 1:10 can be used.

Next, as shown in FIG. 2G and FIG. 2H, p-side contact layer 43 and p-side clad layer 42 are etched using first protective film 95 formed other than the end portion in the resonance direction as a mask. In the present embodiment, as shown in FIG. 2G, entire p-side contact layer 43 at the end portion in the resonance direction and a part of p-side clad layer 42 at the end portion in the resonance direction are removed. As the etching of p-side contact layer 43 and p-side clad layer 42, dry etching by the RIE method using a chlorine-based gas such as Cl₂ can be used.

Next, as shown in FIG. 2I and FIG. 2J, first protective film 95 is selectively removed so that first protective film 95 remains in a band shape extending in the resonance direction (that is, in a shape corresponding to waveguide portion 40a). First protective film 95 can be removed by wet etching using the hydrofluoric acid mentioned above or the like.

Next, as shown in FIG. 2K and FIG. 2L, p-side contact layer 43 and p-side clad layer 42 are etched using first protective film 95 which has been formed in a band-shape as a mask. Accordingly, waveguide portion 40a and flat portion 40b are formed in second semiconductor layer 40. At this time, as shown in FIG. 2M, the end portion shown in FIG. 2J is also etched at the same time. For this reason, at the end portion, p-side clad layer 42, electron barrier layer 41, p-side light guide layer 33, and active layer 32 are removed, and n-side light guide layer 31 is exposed.

Next, as shown in FIG. 2N and FIG. 2P, first protective film 95 formed on waveguide portion 40a is removed by wet etching with hydrofluoric acid or the like, dielectric layer 60 is deposited so as to cover p-side contact layer 43 and p-side clad layer 42. That is, dielectric layer 60 is formed on waveguide portion 40a and flat portion 40b, as well as n-side light guide layer 31 at the end portion. As dielectric layer 60, for example, SiO₂ of 300 nm is deposited by a plasma CVD method using silane (SiH₄).

It should be noted that the deposition method of dielectric layer 60 is not limited to the plasma CVD method, and a deposition method such as a thermal CVD method, a sputtering method, a vacuum vapor deposition method, or a pulse laser deposition method may be used.

Next, as shown in FIG. 2Q, only dielectric layer 60 on waveguide portion 40a is removed by a photolithography method and wet etching using hydrofluoric acid, and the upper surface of p-side contact layer 43 is exposed. After that, as shown in FIG. 2Q and FIG. 2R, the vacuum deposition method and the lift-off method are used to form p-side electrode 51 including the Pd layer and the Pt layer in order from waveguide portion 40a side only on waveguide portion 40a (that is, on p-side contact layer 43 exposed from dielectric layer 60).

It should be noted that the deposition method of p-side electrode 51 is not limited to the vacuum vapor deposition method, and may be a sputtering method, a pulse laser deposition method, or the like. In addition, the electrode material of p-side electrode 51 is only needed to be a material such as a Ni/Au-based or Pt-based material that ohmic-bonds to second semiconductor layer 40 (more specifically, p-side contact layer 43).

Next, as shown in FIG. 2S and FIG. 2T, pad electrode 52 is formed so as to cover p-side electrode 51 and dielectric layer 60. Specifically, by a photolithography method or the like, a resist is patterned on a portion other than the portion where pad electrode 52 is desired to be formed; pad electrode 52 including a Ti layer, a Pt layer and an Au layer in order from the substrate 10 side is formed on the entire surface above substrate 10 by a vacuum vapor deposition method or the like; and the electrode in an unnecessary portion is removed using a lift-off method to form pad electrode 52 having a predetermined shape on p-side electrode 51 and dielectric layer 60. Accordingly, electrode member 50 including p-side electrode 51 and pad electrode 52 is formed.

Next, as shown in FIG. 2U, substrate 10 is thinned. The purpose of this is to facilitate singulation and to improve heat dissipation. Substrate 10 can be thinned by physical and chemical polishing using abrasive grains and a chemical solution. In the present embodiment, substrate 10 having a thickness of 400 μm is thinned to a thickness of about 90 μm. Next, n-side electrode 80 is formed on a main surface below substrate 10 (a main surface on the back side of the main surface on which each semiconductor is deposited). Specifically, n-side electrode 80 including a Ti layer, a Pt layer, and an Au layer in order from the substrate 10 side is formed on the main surface below substrate 10 by a vacuum vapor deposition method or the like, and by patterning using a photolithography method and an etching method, n-side electrode 80 having a predetermined shape is formed.

As described above, semiconductor laser element 1 according to the present embodiment can be manufactured.

### [1-4. Mounting Mode of Semiconductor Laser Element]

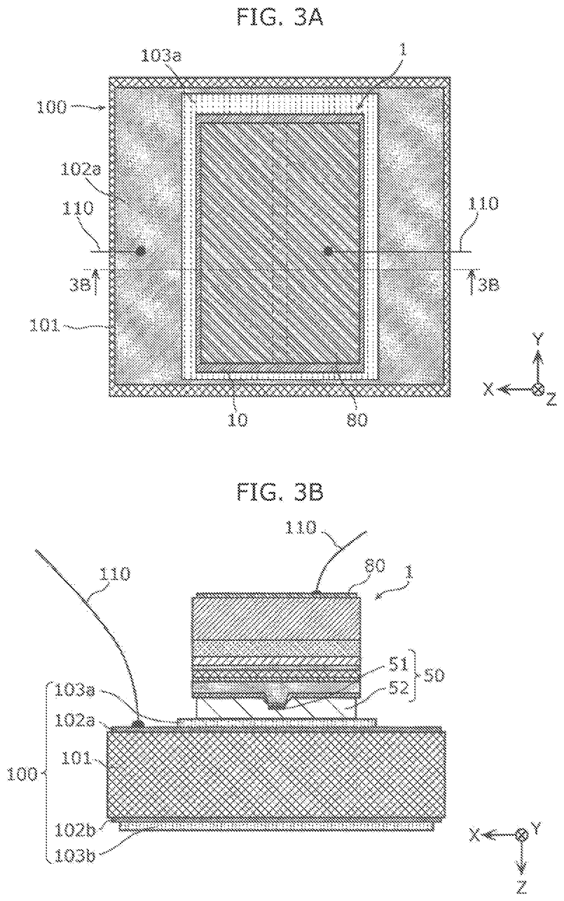

Next, a mounting form of semiconductor laser element 1 according to the present embodiment will be described with reference to FIG. 3A and FIG. 3B. FIG. 3A and FIG. 3B are schematic plan view and cross-sectional view showing a mounting form of semiconductor laser element 1 according to the present embodiment, respectively. FIG. 3B is a cross-sectional view taken along line 3B-3B in FIG. 3A. As shown in FIG. 3B, sub-mount 100 includes base 101, first electrode 102a, second electrode 102b, first adhesive layer 103a, second adhesive layer 103b, and bonding wire 110.

The material of base 101 is not particularly limited. Base 101 may comprise a material having a thermal conductivity higher than or equal to that of semiconductor laser element 1, such as a ceramic such as aluminum nitride (AlN) or silicon carbide (SiC), a simple metal such as diamond (C), Cu, or Al deposited by CVD, or an alloy such as CuW.

First electrode 102a is formed on one surface of base 101. In addition, second electrode 102b is formed on the other surface of base 101 (the surface on the back side of the one surface described above). First electrode 102a and second electrode 102b are deposited films obtained by depositing, for example, a Ti layer having a film thickness of 0.1 μm, a Pt layer having a film thickness of 0.2 μm, and an Au layer having a film thickness of 0.2 μm in order from the base 101 side.

First adhesive layer 103a is formed on first electrode 102a. Second adhesive layer 103b is formed on second electrode 102b. First adhesive layer 103a and second adhesive layer 103b are, for example, eutectic solders comprising a gold-tin alloy having a film thickness of 6 μm containing Au and Sn at 70% and 30%, respectively (hereinafter, referred to as “gold tin solders”).

Bonding wire 110 is a conductive member for supplying an electric current to semiconductor laser element 1. In the present embodiment, one bonding wire 110 is connected to n-side electrode 80 of semiconductor laser element 1, and another bonding wire 110 is connected to first electrode 102a of sub-mount 100.

Semiconductor laser element 1 is mounted on sub-mount 100. Since the present embodiment is a mounting form in which the p side of semiconductor laser element 1 is connected to sub-mount 100, that is, the junction down mounting, electrode member 50 of semiconductor laser element 1 is connected to first adhesive layer 103a of sub-mount 100. It should be noted that when mounting first adhesive layer 103a using gold tin solder as in the present embodiment, the gold tin solder causes a eutectic reaction with the gold contained in pad electrode 52 of electrode member 50 and the gold in first electrode 102a, so that it may be difficult to determine the boundaries. In that case, the film thickness of first adhesive layer 103a here is defined as a distance from the layer that does not eutectic react with gold tin in pad electrode 52 (for example, Pt layer) to the layer that does not eutectic react with gold tin solder in first electrode 102a (for example, Pt layer). It should be noted that although not shown, sub-mount 100 is mounted on a metal package, for example, for the purpose of improving heat dissipation and simplifying handling.

In addition, in the present embodiment, the case where semiconductor laser element 1 is mounted with a junction down mounting has been described, but a mounting form in which the n side of semiconductor laser element 1 is connected to sub-mount 100, that is, a junction up mounting may be applied.

In addition, in the present embodiment, the gold-tin alloy is shown as the material of first adhesive layer 103a, but materials used for known semiconductor bonding such as Sn—Ag-based solder and Sn—Cu-based solder may be used.

### [1-5. Variations]

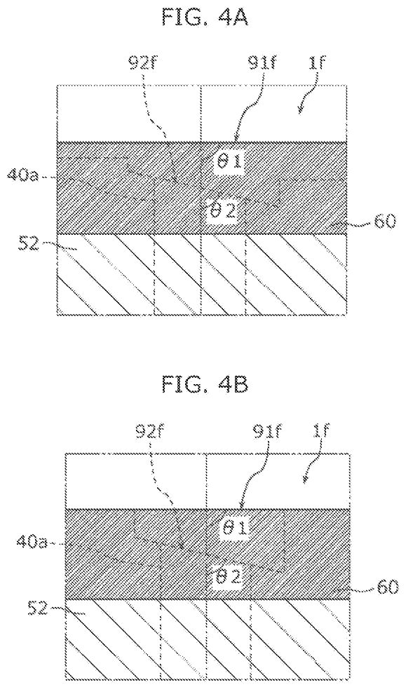

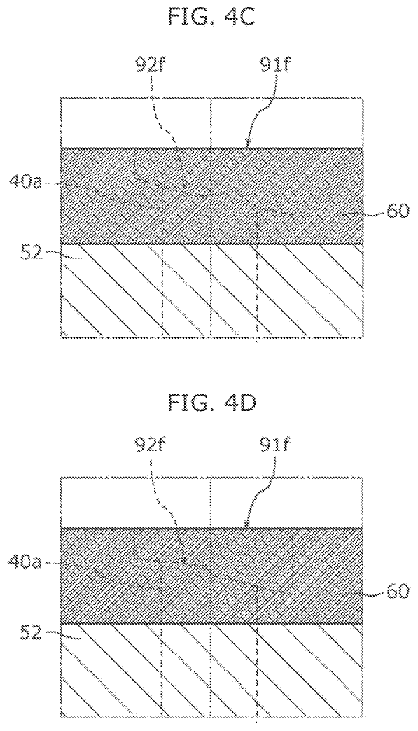

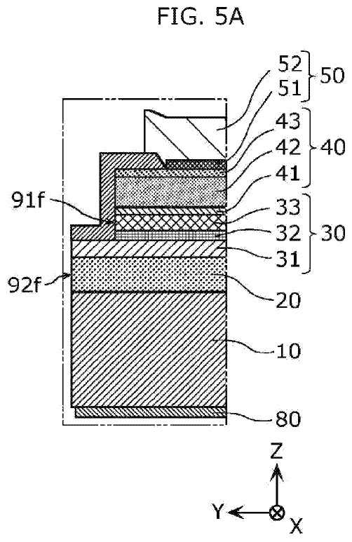

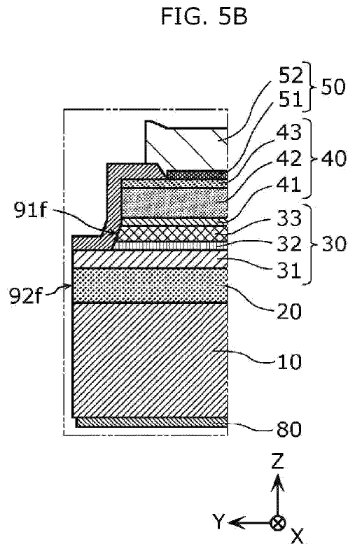

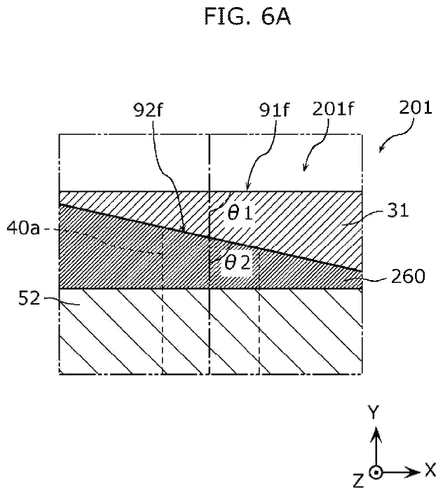

Next, the semiconductor laser elements according to variations of the present embodiment will be described with reference to FIG. 4A to FIG. 4D, FIG. 5A and FIG. 5B. FIG. 4A to FIG. 4D are schematic top views showing a part of front-side end portion 1f of the semiconductor laser element according to the first variation to the fourth variation of the present embodiment in an enlarged manner, respectively. FIG. 4A to FIG. 4D show the structure of the region equivalent to the inside of alternate long and two short dashes line frame 1D shown in FIG. 1A. FIG. 5A and FIG. 5B are schematic cross-sectional views showing a part of front-side end portion 1f of the semiconductor laser element according to the fifth variation and the sixth variation of the present embodiment, respectively, in an enlarged manner. FIG. 5A and FIG. 5B show the structure of the region equivalent to the inside of alternate long and two short dashes line frame 1E shown in FIG. 1C.

In semiconductor laser element 1 according to the First Embodiment described above, entire second end surface 92f of front-side end portion 1f is inclined with respect to first end surface 91f, but as in the semiconductor laser element according to the first variation shown in FIG. 4A, only a part of second end surface 92f may be inclined with respect to first end surface 91f. Of second end surface 92f, at least a part of the portion inclined with respect to first end surface 91f is only needed to be disposed at a position corresponding to waveguide portion 40a.

In addition, in semiconductor laser element 1 according to the First Embodiment described above, entire second end surface 92f of front-side end portion 1f is disposed inside first end surface 91f, but as in the semiconductor laser element according to the second variation shown in FIG. 4B, only a part of second end surface 92f may be disposed inside first end surface 91f and inclined with respect to first end surface 91f. In this case, of second end surface 92f, at least a part of the portion inclined with respect to first end surface 91f is only needed to be disposed at a position corresponding to waveguide portion 40a.

In addition, in semiconductor laser element 1 according to the First Embodiment described above, the inclination of entire second end surface 92f of front-side end portion 1f with respect to first end surface 91f is uniform, but the inclination of second end surface 92f may not be uniform as in the semiconductor laser element according to the second variation shown in FIG. 4C.

In addition, second end surface 92f may have a step as in the semiconductor laser element according to the fourth variation shown in FIG. 4D. In other words, second end surface 92f may have a portion parallel to the resonance direction.

In addition, in semiconductor laser element 1 according to the First Embodiment described above, as shown in FIG. 1E, first end surface 91f is inclined with respect to the normal direction of the main surface viewed from the direction perpendicular to the resonance direction and the normal direction of the main surface of substrate 10. However, first end surface 91f may not be inclined with respect to the normal of the main surface as in the semiconductor laser element according to the fifth variation shown in FIG. 5A. In addition, first end surface 91f may be only partially inclined with respect to the normal of the main surface, as in the semiconductor laser element according to the sixth variation shown in FIG. 5B. In the example shown in FIG. 5B, of first end surface 91f, only the end surfaces of active layer 32 and p-side light guide layer 33 are inclined with respect to the normal of the main surface.

For the semiconductor laser element according to each of the variations as described above, the same effect as that of semiconductor laser element 1 according to the First Embodiment described above is also exhibited.

In addition, in FIG. 4A to FIG. 4D, FIG. 5A and FIG. 5B, only front-side end portion 1f is shown, but the semiconductor laser element may include the same structure at rear-side end portion 1r.

### Second Embodiment

The semiconductor laser element according to the Second Embodiment will be described. The semiconductor laser element according to the present embodiment is different from semiconductor laser element 1 according to the First Embodiment mainly in the configuration of the dielectric layer and the manufacturing method. Hereinafter, the semiconductor laser element according to the present embodiment will be described focusing on the differences from the semiconductor laser element according to the First Embodiment.

### [2-1. Configuration of Semiconductor Laser Element]

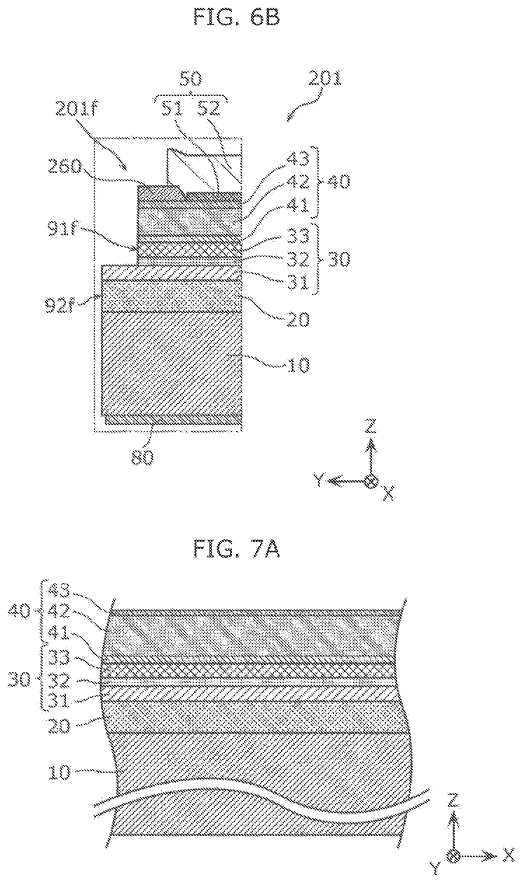

First, the configuration of the semiconductor laser element according to the present embodiment will be described with reference to FIG. 6A and FIG. 6B. FIG. 6A and FIG. 6B are schematic top and sectional views showing a part of front-side end portion 201f of semiconductor laser element 201 according to the present embodiment in an enlarged manner, respectively. FIG. 6A shows the structure of a region equivalent to the inside of alternate long and two short dashes line frame 1D shown in FIG. 1A. FIG. 6B shows the structure of a region equivalent to the inside of alternate long and two short dashes line frame 1E shown in FIG. 1C.

As shown in FIG. 6B, semiconductor laser element 201 according to the present embodiment includes substrate 10, first semiconductor layer 20, light emitting layer 30, second semiconductor layer 40, dielectric layer 260, electrode member 50 and n-side electrode 80. In addition, semiconductor laser element 201 includes first end surface 91f and second end surface 92f at front-side end portion 201f, similarly to semiconductor laser element 1 according to the First Embodiment. Semiconductor laser element 201 according to the present embodiment is different from semiconductor laser element 1 according to the First Embodiment in the configuration of dielectric layer 260.

As shown in FIG. 6A and FIG. 6B, dielectric layer 260 according to the present embodiment is disposed on second semiconductor layer 40, and is not disposed on first end surface 91f and outside thereof. In the present embodiment, dielectric layer 260 is formed of SiO₂ in the same manner as dielectric layer 60 according to the First Embodiment.

Even in semiconductor laser element 201 having such a configuration, the same effect as that of semiconductor laser element 1 according to the First Embodiment is exhibited.

It should be noted that the structure of the rear-side end portion of semiconductor laser element 201 is not particularly limited. For example, the structure of the rear-side end portion of semiconductor laser element 201 may also have the same structure as front-side end portion 201f.

### [2-2. Method for Manufacturing Semiconductor Laser Element]

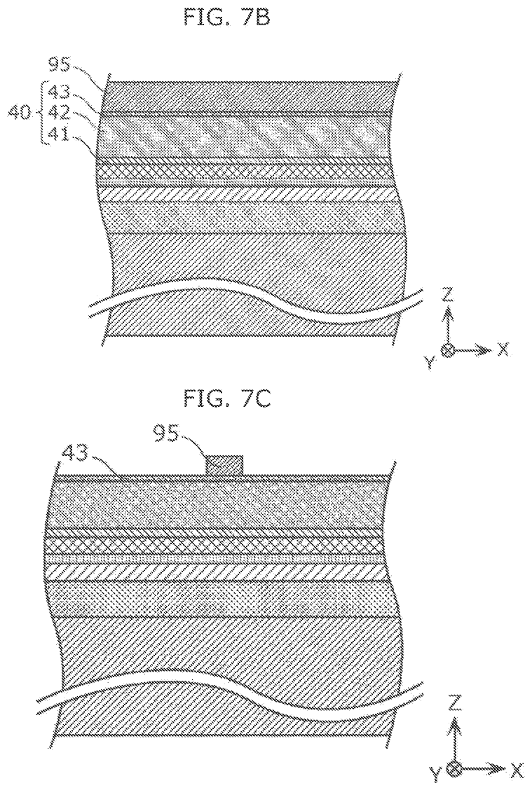

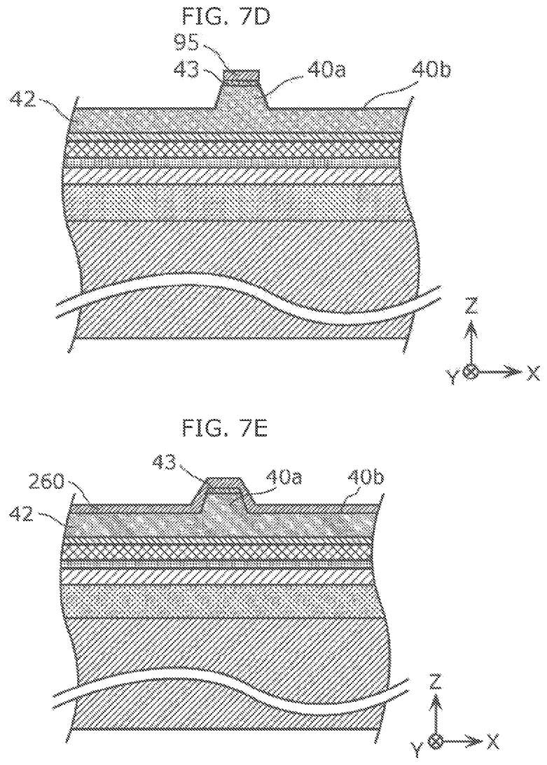

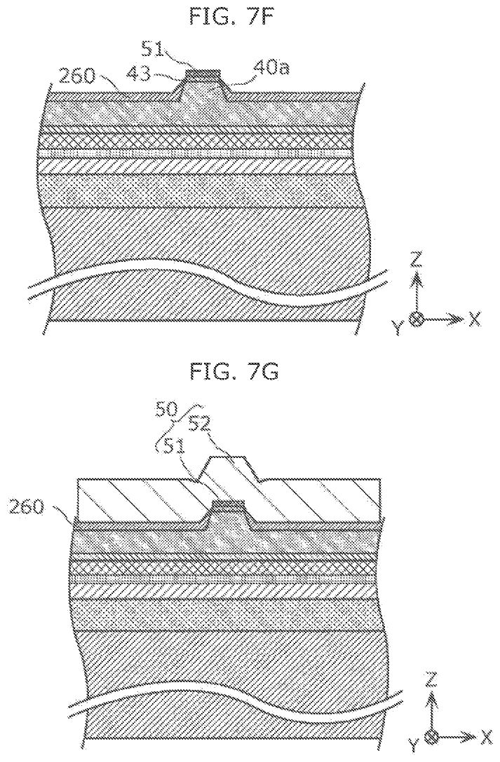

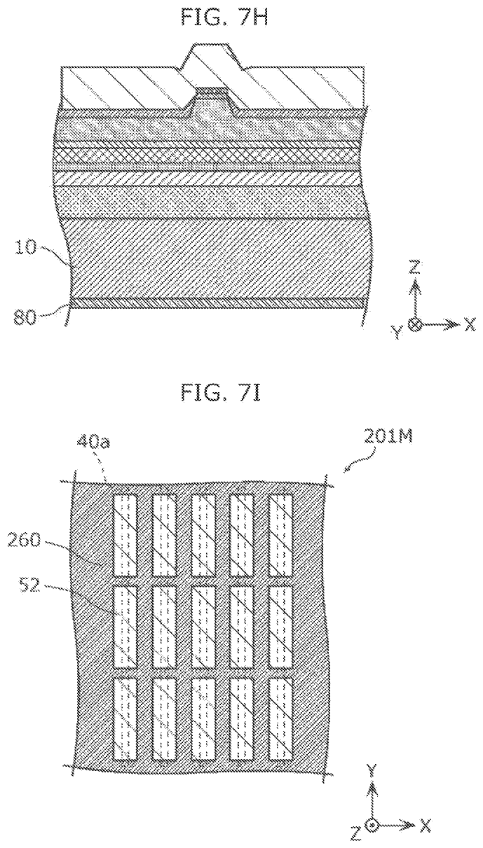

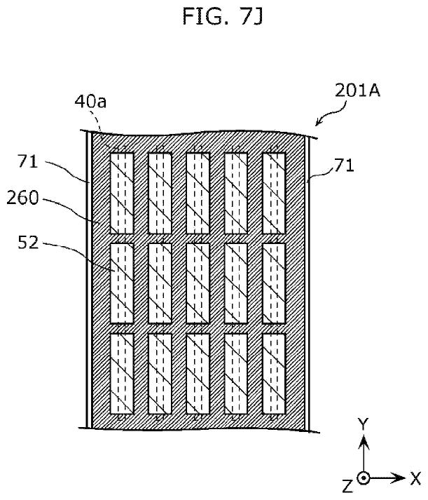

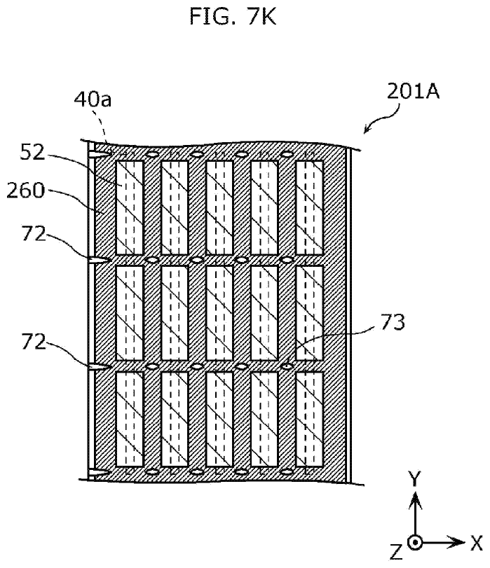

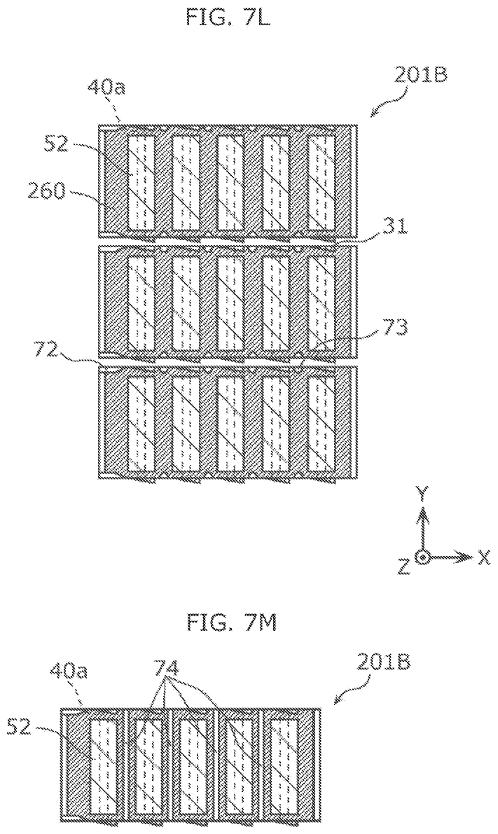

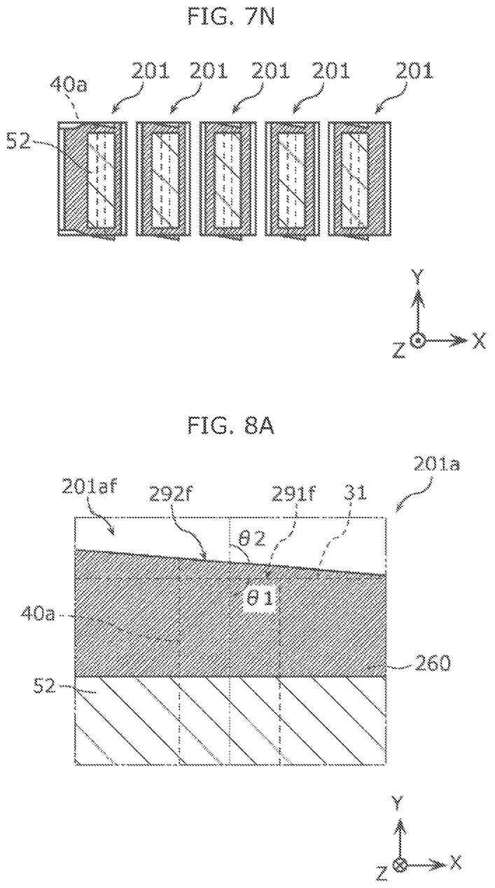

Next, the method for manufacturing semiconductor laser element 201 according to the present embodiment will be described with reference to FIG. 7A to FIG. 7N. FIG. 7A to FIG. 7H are schematic cross-sectional views showing steps in the method for manufacturing semiconductor laser element 201 according to the present embodiment. FIG. 7A to FIG. 7H are cross-sectional views perpendicular to the resonance direction of semiconductor laser element 201. FIG. 7I to FIG. 7N are schematic top views showing steps in the method for manufacturing semiconductor laser element 201 according to the present embodiment.

First, as shown in FIG. 7A, first semiconductor layer 20, light emitting layer 30, and second semiconductor layer 40 are sequentially deposited on substrate 10 as in the First Embodiment. It should be noted that in the present embodiment, a method for manufacturing a plurality of semiconductor laser elements 201 will be described. FIG. 7A to FIG. 7I show steps in the manufacturing process of semiconductor laser elements 201 before they are singulated.

Next, as shown in FIG. 7B, first protective film 95 is deposited on second semiconductor layer 40. Specifically, as in the First Embodiment, a SiO₂ film of 300 nm is deposited on p-side contact layer 43 as first protective film 95.

Next, as shown in FIG. 7C, first protective film 95 is selectively removed so that first protective film 95 remains in a band shape extending in the resonance direction (that is, a shape corresponding to waveguide portion 40a). It should be noted that although not shown in FIG. 7C, a plurality of band-shaped first protective films 95 extending in the resonance direction are formed.

Next, as shown in FIG. 7D, p-side contact layer 43 and p-side clad layer 42 are etched using band-shaped first protective film 95 as a mask. Accordingly, waveguide portion 40a and flat portion 40b are formed in second semiconductor layer 40. It should be noted that although not shown in FIG. 7D, a plurality of waveguide portions 40a extending in the resonance direction are formed.

Next, as shown in FIG. 7E, first protective film 95 formed on waveguide portion 40a is removed, and dielectric layer 260 is deposited so as to cover p-side contact layer 43 and p-side clad layer 42. As dielectric layer 260, SiO₂ of 300 nm is deposited.

Next, as shown in FIG. 7F, only dielectric layer 260 on waveguide portion 40a is removed to expose the upper surface of A-side contact layer 43. After that, p-side electrode 51 including a Pd layer and a Pt layer is formed only on waveguide portion 40a in order from waveguide portion 40a side.

Next, as shown in FIG. 7G, pad electrode 52 is formed so as to cover p-side electrode 51 and dielectric layer 260. Specifically, the resist is patterned in a portion other than the portion where pad electrode 52 is desired to be formed. After that, pad electrode 52 including a Ti layer, a Pt layer, and an Au layer in order from the substrate 10 side is formed on the entire surface above substrate 10 by a vacuum vapor deposition method or the like. After that, the electrode in an unnecessary portion is removed using a lift-off method. In this way, pad electrode 52 having a predetermined shape is formed on p-side electrode 51 and dielectric layer 260. Accordingly, electrode member 50 including p-side electrode 51 and pad electrode 52 is formed. It should be noted that although not shown, electrode member 50 is formed on each of the plurality of waveguide portions 40a.

Next, as shown in FIG. 7H, substrate 10 is thinned. In the present embodiment as well as in the First Embodiment, substrate 10 having a thickness of 400 μm is thinned to a thickness of about 90 μm. Next, n-side electrode 80 is formed on the main surface below substrate 10. Specifically, n-side electrode 80 including a Ti layer, a Pt layer, and an Au layer in order from the substrate 10 side is formed on the main surface below substrate 10 by a vacuum vapor deposition method or the like, and by patterning using a photolithography method and an etching method, n-side electrode 80 having a predetermined shape is formed. It should be noted that although not shown, a plurality of n-side electrodes 80 are formed, and each n-side electrode 80 is arranged at a position opposite to each of the plurality of electrode members 50.

By the above steps, as shown in FIG. 7I, base material 201M in which a plurality of pad electrodes 52 (and p-side electrodes 51) are arranged in a matrix is formed.

Next, as shown in FIG. 7J, grooves 71 extending in the resonance direction are formed in base material 201M shown in FIG. 7I, and base material 201M is divided along grooves 71 to form divided material 201A. In the example shown in FIG. 7J, five waveguide portions 40a are arranged between two adjacent grooves 71. That is, one groove 71 is formed for every five waveguide portions 40a. Groove 71 can be formed by using, for example, a diamond cutter, a laser scribe, or the like. The depth of groove 71 is only needed to be 10 μm or more. In the present embodiment, the depth of groove 71 is 30 μm. Subsequently, base metal 201M is divided along such grooves 71. It should be noted that in FIG. 7J, grooves 71 are formed on the main surface on the upper side of substrate 10 (the main surface on the side where first semiconductor layer 20 and the like are disposed), but they may be formed on the main surface on the lower side of substrate 10 (the main surface on the side where n-side electrode 80 is disposed).

Next, as shown in FIG. 7K, grooves 72 are formed at one end portion of divided member 201A in the X-axis direction along the resonance direction and the direction perpendicular to the normal direction of the main surface of substrate 10 (that is, the X-axis direction). In the present embodiment, groove 72 is formed between the adjacent pad electrodes 52 in the resonance direction (that is, the Y-axis direction). In addition, dot-shaped grooves 73 which are arranged between adjacent pad electrodes 52 in the resonance direction and between two adjacent waveguide portions 40a in the direction perpendicular to the resonance direction and the normal direction of the main surface of substrate 10 (that is, the X-axis direction) are formed. The depth and forming method of grooves 72 and grooves 73 are the same as those of grooves 71. It should be noted that in FIG. 7K, grooves 72 and grooves 73 are formed on the main surface on the upper side of substrate 10, but may be formed on the main surface on the lower side of substrate 10.

Next, as shown in FIG. 7L, divided material 201A is divided along grooves 72 perpendicularly to the resonance direction. Accordingly, bar-shaped members 201B are formed. In this way, when divided material 201A is divided, first end surface 91f and second end surface 92f of semiconductor laser element 201 are formed. That is, the front-side end surface of first semiconductor layer 20 and the like and the front-side end surface of second semiconductor layer 40 and the like are not formed on the same plane, and the front-side end surface of second semiconductor layer 40 or the like includes an inclined portion with respect to the front-side end surface of first semiconductor layer 20 and the like. Such an end surface structure is formed by, for example, the following dividing method. When dividing divided material 201A at the position of groove 72, a force is applied in order from the left side to the right side in FIG. 7K. At this time, the direction in which the force is applied is slightly inclined from the X-axis direction in FIG. 7K (that is, a force is applied so that divided member 201A is divided along the direction slightly inclined from the X-axis direction). Even if the force is applied in this way, the dividing surface is guided to groove 73, so that divided material 201A is divided substantially along the X-axis direction, and an end surface structure as in semiconductor laser element 201 according to the present embodiment is formed.

Next, as shown in FIG. 7M, grooves 74 are formed along the resonance direction between two adjacent pad electrodes 52 in the X-axis direction of bar-shaped member 201B. The depth and forming method of grooves 74 are the same as those of groove 71. In addition, grooves 74 may be formed on either the main surface on the upper side or the main surface on the lower side of substrate 10 similarly to grooves 71.

Next, as shown in FIG. 7N, bar-shaped member 201B is divided along grooves 74. Accordingly, semiconductor laser elements 201 are formed.

### [2-3. Variations]

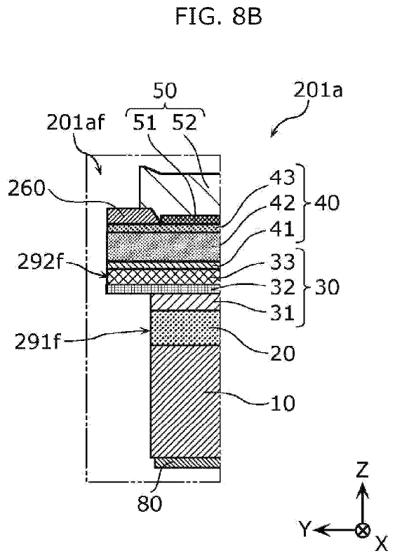

Next, the semiconductor laser element according to a variation of the present embodiment will be described. In the present variation, the positional relationship between the first end surface and the second end surface is different from that of semiconductor laser element 201 according to the Second Embodiment. Hereinafter, the semiconductor laser element according to the present variation will be described with reference to FIG. 8A and FIG. 8B, focusing on the differences from semiconductor laser element 201 according to the Second Embodiment.

FIG. 8A and FIG. 8B are schematic top view and sectional view showing a part of front-side end portion 201af of semiconductor laser element 201a according to the present variation in an enlarged manner, respectively. FIG. 8A shows the structure of a region equivalent to the inside of alternate long and two short dashes line frame 1D shown in FIG. 1A. FIG. 8B shows the structure of a region equivalent to the inside of alternate long and two short dashes line frame 1E shown in FIG. 1C.

As shown in FIG. 8B, semiconductor laser element 201a according to the present variation includes substrate 10, first semiconductor layer 20, light emitting layer 30, second semiconductor layer 40, dielectric layer 260, electrode member 50, and n-side electrode 80. In addition, semiconductor laser element 201a includes first end surface 291f and second end surface 292f at front-side end portion 201f, similarly to semiconductor laser element 1 according to the First Embodiment. First end surface 291f is a flat surface portion formed by the end surfaces of substrate 10, first semiconductor layer 20, and n-side light guide layer 31 at front-side end portion 201af of semiconductor laser element 201a. Second end surface 292f is a flat surface portion formed by the end surfaces of p-side light guide layer 33 and second semiconductor layer 40 at front-side end portion 201af of semiconductor laser element 201a.

As shown in FIG. 8A, also in semiconductor laser element 201a according to the present variation, the end surface of second end surface 292f includes a portion inclined with respect to the end surface of first end surface 291f in the top view of front-side end portion 201af. In the present variation, the end surface of second end surface 292f is disposed outside the end surface of first end surface 291f.

Even in semiconductor laser element 201a having such a configuration, the same effect as that of semiconductor laser element 201 according to the Second Embodiment is exhibited.

In addition, front-side end portion 201af of semiconductor laser element 201a according to the present variation has a shape corresponding to front-side end portion 201f of semiconductor laser element 201 according to the Second Embodiment. For that reason, it can be formed by the same manufacturing method as semiconductor laser element 201 according to the Second Embodiment. That is, when divided member 201A is divided into bar-shaped member 201B as shown in FIG. 7L, when front-side end portion 201f of semiconductor laser element 201 according to the Second Embodiment is formed on one end surface, front-side end portion 201af of semiconductor laser element 201a according to the present variation is formed on the other end surface. In this way, front-side end portion 201af of semiconductor laser element 201a according to the present variation can be formed.

### Third Embodiment

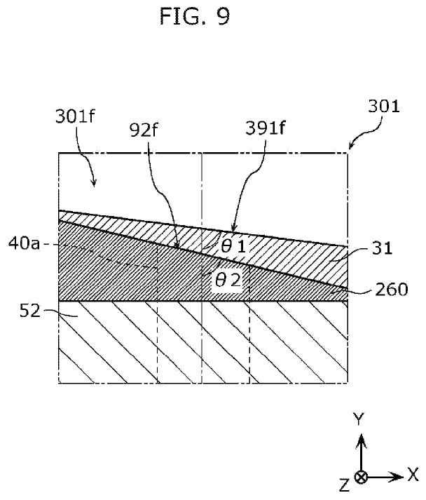

The semiconductor laser element according to the Third Embodiment will be described. The semiconductor laser element according to the present embodiment is different from semiconductor laser element 201 according to the Second Embodiment in the configuration of the first end surface. Hereinafter, the semiconductor laser element according to the present embodiment will be described with reference to FIG. 9, focusing on the differences from semiconductor laser element 201 according to the Second Embodiment.

FIG. 9 is a schematic top view showing a part of front-side end portion 301f of semiconductor laser element 301 according to the present embodiment in an enlarged manner. FIG. 9 shows the structure of a region equivalent to the inside of alternate long and two short dashes line frame 1D shown in FIG. 1A.

As shown in FIG. 9, similarly to the Second Embodiment, in the top view of front-side end portion 301f of semiconductor laser element 301 according to the present embodiment, second end surface 92f includes an inclined portion with respect to first end surface 391f.

Semiconductor laser element 301 according to the present embodiment is different from semiconductor laser element 201 according to the Second Embodiment in that first end surface 391f is inclined with respect to the X-axis direction in FIG. 9 in the top view of front-side end portion 301f. Even in semiconductor laser element 301 having such a configuration, second end surface 92f has a portion inclined with respect to first end surface 391f, so that the same effect as that of semiconductor laser element 201 according to the Second Embodiment is exhibited.

It should be noted that semiconductor laser element 301 according to the present embodiment can be formed, for example, by inclining the arrangement direction of grooves 73 with respect to the X-axis direction in the method for manufacturing semiconductor laser element 201 according to the Second Embodiment.

### Fourth Embodiment

The semiconductor laser element according to the Fourth Embodiment will be described. The semiconductor laser element according to the present embodiment is different from semiconductor laser element 201 according to the Second Embodiment mainly in that it includes a plurality of waveguide portions. Hereinafter, the semiconductor laser element according to the present embodiment will be described focusing on the differences from semiconductor laser element 201 according to the Second Embodiment.

### [4-1. Configuration of Semiconductor Laser Element]

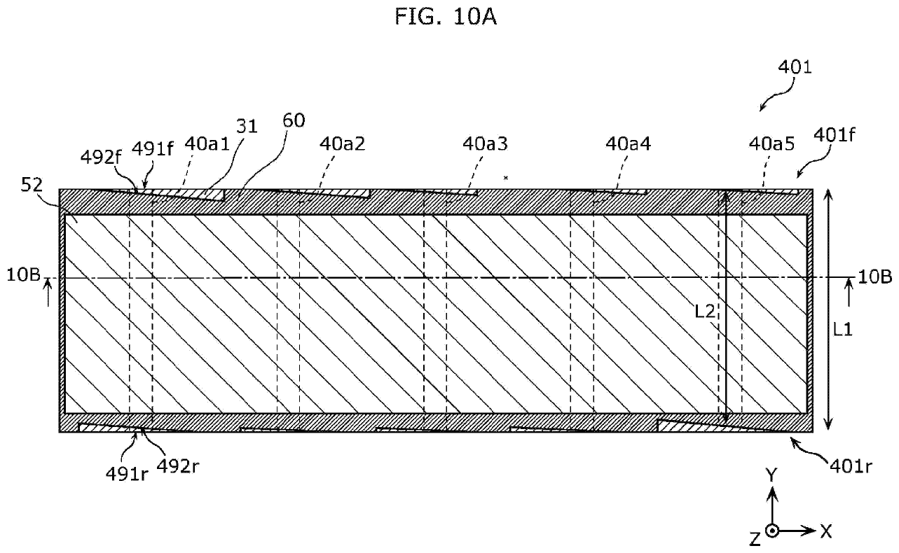

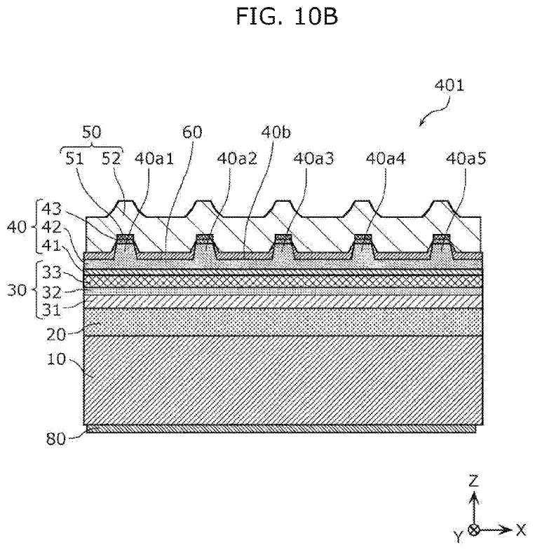

First, the configuration of semiconductor laser element 401 according to the present embodiment will be described with reference to FIG. 10A and FIG. 10B. FIG. 10A and FIG. 10B are schematic top view and sectional view showing the configuration of semiconductor laser element 401 according to the present embodiment, respectively. FIG. 10B is a cross-sectional view taken along line 10B-10B of FIG. 10A.

Similar to semiconductor laser element 201 according to the Second Embodiment, semiconductor laser element 401 according to the present embodiment includes substrate 10, first semiconductor layer 20, light emitting layer 30, second semiconductor layer 40, electrode member 50, dielectric layer 60, and n-side electrode 80 as shown in FIG. 10B.

Semiconductor laser element 401 according to the present embodiment includes a plurality of waveguide portions arranged in an array. In the present embodiment, second semiconductor layer 40 includes five waveguide portions 40a1 to 40a5 arranged in the X-axis direction. The configuration of each waveguide portion is the same as that of waveguide portion 40a of second semiconductor layer 40 according to the Second Embodiment. In FIG. 10A, waveguide portion 40a1, waveguide portion 40a2, waveguide portion 40a3, waveguide portion 40a4, and waveguide portion 40a5 are arranged in order from the bottom to the top of the page. In addition, in FIG. 10B, waveguide portion 40a1, waveguide portion 40a2, waveguide portion 40a3, waveguide portion 40a4, and waveguide portion 40a5 are arranged in order from the left to the right of the page.

In this way, since semiconductor laser element 401 includes a plurality of waveguide portions, the total power of the output beams from the plurality of waveguide portions can be increased relative to the power of the output beam of the semiconductor laser element according to each of the above embodiments. For example, by combining the output beams from a plurality of waveguides, a higher power laser beam can be obtained.

Even in the present embodiment, similar to the Second Embodiment, as shown in FIG. 10A, in the top view of front-side end portion 401f of semiconductor laser element 401, second end surface 492f includes an inclined portion with respect to first end surface 491f. In the present embodiment, second end surface 492f is inclined with respect to first end surface 491f in each waveguide portion.

In addition, in the top view of rear-side end portion 401r of semiconductor laser element 401, second end surface 492r includes a portion inclined with respect to first end surface 491r. In the present embodiment, second end surface 492r is inclined with respect to first end surface 491r in each waveguide portion.

By providing such an end surface structure, in semiconductor laser element 401 according to the present embodiment, the same effect as that of semiconductor laser element 201 according to the Second Embodiment is exhibited.

In addition, in the present embodiment, in the top view of front-side end portion 401f, the inclination angles of the end surfaces of second end surfaces 492f with respect to first end surfaces 491f are different in positions corresponding to at least two of the plurality of waveguide portions. That is, in the top view of front-side end portion 401f, the inclination angles of the end surfaces of second semiconductor layer 40 with respect to the end surfaces of first semiconductor layer 20 are different from each other at the positions corresponding to at least two of the plurality of waveguide portions.

This makes it possible to make the generated higher-order transverse mode components different in at least two of the plurality of waveguide portions. Therefore, the ripples contained in the light distributions of at least two laser beams are different. For this reason, when a plurality of laser beams emitted from the respective waveguides are combined, it is possible to suppress the ripples contained in at least two light distributions of laser beams from intensifying each other. That is, it is possible to suppress the ripples in the combined laser beam generated by combining a plurality of laser beams.

In the present embodiment, in the top view of front-side end portion 401f, the inclination angles of the end surfaces of second end surfaces 492f with respect to first end surfaces 491f are different from the others at the positions corresponding to all of the plurality of waveguide portions.

In the present embodiment, even in the top view of rear-side end portion 401r, similar to front-side end portion 401f, the inclination angles of the end surfaces of second end surfaces 492r with respect to first end surfaces 491r are different from each other at the positions corresponding to at least two of the plurality of waveguide portions. That is, in the top view of rear-side end portion 401r, the inclination angles of the end surfaces of second semiconductor layer 40 with respect to the end surfaces of first semiconductor layer 20 are different from each other at the positions corresponding to at least two of the plurality of waveguide portions.

This makes it possible to further suppress ripples in the combined laser beam generated by combining a plurality of laser beams emitted from semiconductor laser elements 401.

In the present embodiment, in the top view of rear-side end portion 401r, the inclination angles of the end surfaces of second end surfaces 492r with respect to first end surface 491r are different from the others at the positions corresponding to all of the plurality of waveguide portions.

In addition, in the present embodiment, in the top view of front-side end portion 401f, the inclination directions of the end surfaces of second end surfaces 492f with respect to first end surface 491f are the same at the positions corresponding to at least two of the plurality of waveguide portions. That is, in the top view of front-side end portion 401f, the inclination directions of the end surfaces of second semiconductor layer 40 with respect to the end surfaces of first semiconductor layer 20 are the same at the positions corresponding to at least two of the plurality of waveguide portions.

Furthermore, in the top view of front-side end portion 401f, the inclination directions of the end surfaces of second end surfaces 492f with respect to first end surface 491f are the same at the positions corresponding to all of the plurality of waveguide portions. That is, in the top view of front-side end portion 401f, the inclination directions of the end surfaces of second semiconductor layer 40 with respect to the end surfaces of first semiconductor layer 20 are the same at the positions corresponding to all of the plurality of waveguide portions.

In addition, even in the top view of rear-side end portion 401r, the inclination directions of the end surfaces of second end surfaces 492r with respect to first end surface 491r are the same at the positions corresponding to all of the plurality of waveguide portions, similar to front-side end portion 401f. That is, in the top view of rear-side end portion 401r, the inclination directions of the end surfaces of second semiconductor layer 40 with respect to the end surfaces of first semiconductor layer 20 are the same at the positions corresponding to all of the plurality of waveguide portions.

### [4-2. Action and Effect]

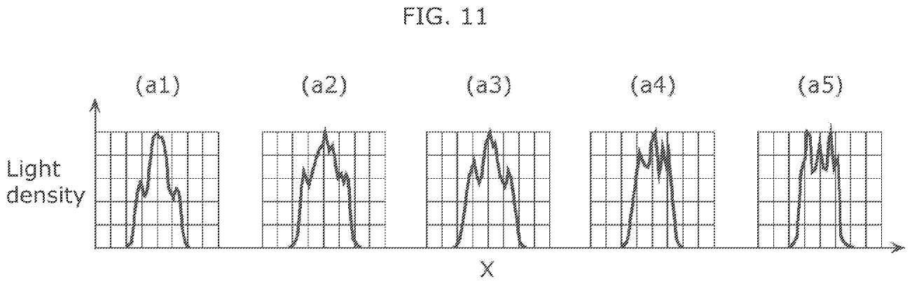

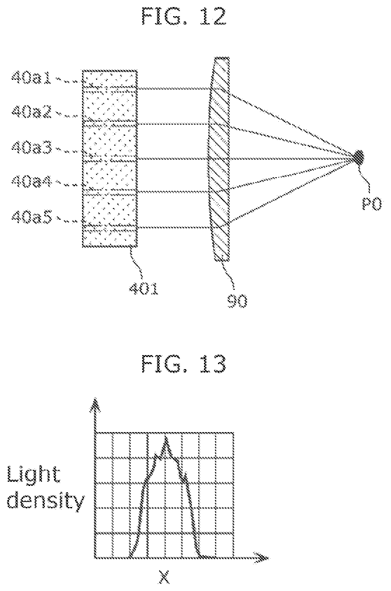

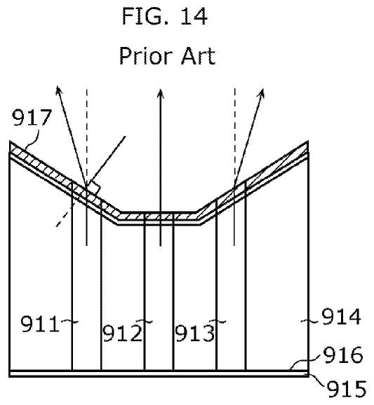

Next, the action and effect of semiconductor laser element 401 according to the present embodiment will be described with reference to FIG. 11 to FIG. 13. FIG. 11 includes graphs showing an example of the light density distributions of the laser beams emitted from the respective waveguide portions according to the present embodiment. Graphs a1 to a5 in FIG. 11 show the light density distributions of the laser beam emitted from the waveguide portions 40a1 to 40a5, respectively. FIG. 12 is a schematic diagram showing an optical system that condenses five laser beams emitted from semiconductor laser elements 401 according to the present embodiment to one point PO. FIG. 13 is a graph showing the light density distribution of the combined beam in which the five laser beams emitted from semiconductor laser elements 401 according to the present embodiment are focused by the optical system shown in FIG. 12. It should be noted that X shown in FIG. 11 and FIG. 13 indicates a predetermined position in the X-axis direction in the vicinity of the end surfaces of optical waveguide portions 401a1 to 401a5 or semiconductor laser element 401.

As shown in FIG. 11, by making the inclination angle of second end surface 492f (and second end surface 492r) with respect to first end surface 491f (and first end surface 491r) in each waveguide portion different, the light density distribution of the beam emitted from each waveguide portion changes. That is, the positions and magnitudes of the ripples in the light density distribution change. In other words, by making the inclination angle of second end surface 492f (and second end surface 492r) with respect to first end surface 491f (and first end surface 491r) in each waveguide portion different, the order of the higher-order modes included in the laser beam and the intensity of the higher-order modes change.

By condensing the five laser beams having the light density distributions as shown in FIG. 11 by condensing optical system 90 shown in FIG. 12, the beams can be condensed to one point PO. As condensing optical system 90, for example, a cylindrical lens or the like can be used.

When five laser beams having the light density distributions as shown in FIG. 11 are condensed, the positions of the ripples in the light density distribution of each laser beam are different from those of other laser beams, so that the ripples included in the light density distribution are partially cancelled out. Therefore, according to semiconductor laser element 401 according to the present embodiment, it is possible to suppress the ripples in the combined beam of the beams emitted from the plurality of waveguide portions 40a1 to 40a5.

(Variations)

The semiconductor laser element according to the present disclosure has been described above based on the embodiments, but the present disclosure is not limited to the above embodiments.

For example, the composition of each layer included in the nitride-based semiconductor laser element is not limited to the above, and a nitride-based semiconductor laser element can be configured by appropriately combining a plurality of layers which are nitride semiconductors in which at least two layers have different predetermined compositions, that is, AlₓIn_{y}Ga_{1-x-y}N (0≤x≤1, 0≤y≤1). The composition of the active layer can also be appropriately changed in order to obtain a desired emission wavelength. In addition, the layer thickness of each layer included in the nitride semiconductor laser element is not limited to the above, either.

In addition, for example, in each of the above embodiments, the semiconductor laser element is a nitride-based semiconductor laser element, but the configuration of the semiconductor laser element is not limited thereto. For example, the semiconductor laser element may be a semiconductor laser element including a semiconductor other than a nitride-based semiconductor material, or may be, for example, a semiconductor laser element including a gallium arsenic-based semiconductor material.

In addition, forms obtained by applying various modifications to the above embodiments conceived by a person skilled in the art or forms realized by arbitrarily combining the components and functions in each embodiment without departing from the spirit of the present disclosure are also included in this disclosure.

### INDUSTRIAL APPLICABILITY

The semiconductor laser element according to the present disclosure can be used as a light source for an image display device, lighting, industrial equipment, or the like, and is particularly useful as a light source for equipment that requires a relatively high light output.

1. A semiconductor laser element comprising:
a substrate;
a first semiconductor layer disposed above a main surface of the substrate;
an active layer that is disposed above the first semiconductor layer and generates light; and
a second semiconductor layer disposed above the active layer,
wherein in a top view of a front-side end portion of the semiconductor laser element from which the light is emitted, an end surface of the second semiconductor layer includes an inclined portion with respect to an end surface of first semiconductor layer.

2. The semiconductor laser element according to claim 1,
wherein in a top view of a rear-side end portion, which is an end portion opposite to the front-side end portion, an end surface of the second semiconductor layer includes an inclined portion with respect to an end surface of the first semiconductor layer.

3. The semiconductor laser element according to claim 2,
wherein the inclined portion of the front-side end portion and the inclined portion of the rear-side end portion that is opposite to the inclined portion of the front-side end portion are not parallel in a top view.

4. The semiconductor laser element according to claim 2,
wherein the inclined portion of the front-side end portion and the inclined portion of the rear-side end portion are tilted in a same direction with respect to the end surface of the first semiconductor layer around an axis perpendicular to the main surface.

5. The semiconductor laser element according to claim 1,
wherein the semiconductor laser element comprises a plurality of waveguide portions arranged in an array, and
in the top view of the front-side end portion, inclination angles of end surfaces of the second semiconductor layer with respect to end surfaces of the first semiconductor layer differ from each other at positions corresponding to at least two of the plurality of waveguide portions.

6. The semiconductor laser element according to claim 1,
wherein the semiconductor laser element comprises a plurality of waveguide portions arranged in an array, and
in the top view of the front-side end portion, inclination directions of end surfaces of the second semiconductor layer with respect to end surfaces of the first semiconductor layer are same at positions corresponding to at least two of the plurality of waveguide portions.

7. The semiconductor laser element according to claim 6,
wherein in the top view of the front-side end portion, the inclination directions of the end surfaces of the second semiconductor layer with respect to the end surfaces of the first semiconductor layer are same at positions corresponding to all of the plurality of waveguide portions.

8. The semiconductor laser element according to claim 1,
wherein in the top view of the front-side end portion, an inclination angle of the end surface of the second semiconductor layer with respect to the end surface of the first semiconductor layer is 0.1 degrees or more.
